(19) United States
(12) Patent Application Publication
(10) Pub. No.: US 2021/0358925 A1
(43) Pub. Date: Nov. 18, 2021

(54) SEMICONDUCTOR MEMORY DEVICE

(71) Applicant: Kioxia Corporation, Tokyo (JP)

(72) Inventors: Kota TAKAHASHI, Yokkaichi (JP); Kazuhiro MATSUO, Kuwana (JP); Shinji MORI, Nagoya (JP); Yuta KAMIYA, Yokkaichi (JP); Kenichiro TORATANI, Yokkaichi (JP)

(73) Assignee: Kioxia Corporation, Tokyo (JP)

(21) Appl. No.: 17/194,629

(22) Filed: Mar. 8, 2021

(30) Foreign Application Priority Data
May 15, 2020 (JP) 2020-085611

(51) Int. Cl. H01L 27/1159; H01L 27/11587; H01L 27/11597

(52) U.S. Cl. CPC H01L 27/1159; H01L 27/11597; H01L 27/11587

(57) ABSTRACT

A memory device of an embodiment includes a stacked body including a plurality of insulating layers and a plurality of gate electrode layers alternately stacked in a first direction, a semiconductor layer provided in the stacked body and extending in the first direction, and a gate insulating layer provided between the semiconductor layer and the gate electrode layer, the gate insulating layer including a first region including a first oxide containing at least one of hafnium oxide or zirconium oxide, the first region including an orthorhombic crystal, and the first region including at least one first element selected from the group consisting of carbon (C), nitrogen (N), chlorine (Cl), boron (B), hydrogen (H), fluorine (F), helium (He), and argon (Ar).

### CROSS-REFERENCE TO RELATED APPLICATION

This application is based upon and claims the benefit of priority from Japanese Patent Application No. 2020-085611, filed on May 15, 2020, the entire contents of which are incorporated herein by reference.

### FIELD

Embodiments described herein relate generally to a memory device.

### BACKGROUND

Ferroelectric memory is noticed as a nonvolatile memory. Examples of the ferroelectric memory are, a 3-terminal type memory in which a gate insulating layer of a memory cell transistor is a ferroelectric layer, and a 2-terminal type memory in which a ferroelectric layer is provided between two electrodes, such as a ferroelectric tunnel junction (FTJ) memory. Using the polarization inversion of the ferroelectric, the ferroelectric memory writes data to the memory cell and erases the data of the memory cell.

For example, in a 3-terminal type ferroelectric memory, the polarization inversion state of a gate insulating layer of the memory cell transistor is controlled by a voltage applied between the gate electrode and the semiconductor layer. The threshold voltage of the memory cell transistor changes depending on the polarization inversion state of the gate insulating layer.

When the threshold voltage of the memory cell transistor changes, the on-current of the memory cell transistor changes. For example, if a state where the threshold voltage is high and the on-current is low is defined as data “0”, and a state where the threshold voltage is low and the on-current is high is defined as data “1”, the memory cell can store 1-bit data of “0” and “1”. In a 3-terminal type ferroelectric memory, it is desired to enlarge the difference between the threshold voltage in the state where the on-current is low and the threshold voltage in the state where the on-current is high, i.e., the so-called memory window.

Enlarging the memory window stabilizes the operation of the ferroelectric memory, for example. Enlarging the memory window makes it easy to provide a multivalued memory cell of the ferroelectric memory, for example.

### BRIEF DESCRIPTION OF THE DRAWINGS

FIG. 1 is a circuit diagram of a memory cell array of a memory device according to a first embodiment;

FIGS. 2A and 2B are schematic cross-sectional views of a part of the memory cell array of the memory device of the first embodiment;

FIG. 3 is a schematic cross-sectional view of a memory cell of the memory device of the first embodiment;

FIG. 4 is a schematic cross-sectional view showing a manufacturing method of a memory device of the first embodiment;

FIG. 5 is a schematic cross-sectional view showing the manufacturing method of the memory device of the first embodiment;

FIG. 6 is a schematic cross-sectional view showing the manufacturing method of the memory device of the first embodiment;

FIG. 7 is a schematic cross-sectional view showing the manufacturing method of the memory device of the first embodiment;

FIG. 8 is a schematic cross-sectional view showing the manufacturing method of the memory device of the first embodiment;

FIG. 9 is a schematic cross-sectional view showing the manufacturing method of the memory device of the first embodiment;

FIG. 10 is a schematic cross-sectional view showing the manufacturing method of the memory device of the first embodiment;

FIG. 11 is a schematic cross-sectional view showing the manufacturing method of the memory device of the first embodiment;

FIG. 12 is a schematic cross-sectional view of a memory cell of a memory device of a variation of the first embodiment;

FIGS. 13A and 13B are schematic cross-sectional views of a part of the memory cell array of a memory device of a second embodiment;

FIG. 14 is a schematic cross-sectional view of a memory cell of the memory device of the second embodiment;

FIG. 15 is a schematic cross-sectional view showing a manufacturing method of the memory device of the second embodiment;

FIG. 16 is a schematic cross-sectional view showing the manufacturing method of the memory device of the second embodiment;

FIG. 17 is a schematic cross-sectional view showing the manufacturing method of the memory device of the second embodiment;

FIG. 18 is a schematic cross-sectional view showing the manufacturing method of the memory device of the second embodiment;

FIG. 19 is a schematic cross-sectional view showing the manufacturing method of the memory device of the second embodiment;

FIG. 20 is a schematic cross-sectional view showing the manufacturing method of the memory device of the second embodiment;

FIG. 21 is a schematic cross-sectional view showing the manufacturing method of the memory device of the second embodiment;

FIG. 22 is a schematic cross-sectional view showing the manufacturing method of the memory device of the second embodiment;

FIGS. 23A and 23B are schematic cross-sectional views of a part of the memory cell array of a memory device of a variation of the second embodiment;

FIGS. 24A and 24B are schematic cross-sectional views of a part of the memory cell array of a memory device of a third embodiment;

FIG. 25 is a schematic cross-sectional view of a memory cell of the memory device of the third embodiment;

FIG. 26 is a schematic cross-sectional view showing a manufacturing method of the memory device of a third embodiment;

FIG. 27 is a schematic cross-sectional view showing a manufacturing method of the memory device of the third embodiment;

FIG. 28 is a schematic cross-sectional view showing a manufacturing method of the memory device of the third embodiment;

FIG. 29 is a schematic cross-sectional view showing a manufacturing method of the memory device of the third embodiment;

FIG. 30 is a schematic cross-sectional view showing a manufacturing method of the memory device of the third embodiment;

FIG. 31 is a schematic cross-sectional view showing a manufacturing method of the memory device of the third embodiment;

FIG. 32 is a schematic cross-sectional view showing a manufacturing method of the memory device of the third embodiment;

FIG. 33 is a schematic cross-sectional view showing a manufacturing method of the memory device of the third embodiment;

FIG. 34 is a schematic cross-sectional view showing a manufacturing method of the memory device of the third embodiment;

FIG. 35 is a schematic cross-sectional view showing a manufacturing method of the memory device of the third embodiment;

FIG. 36 is a schematic cross-sectional view showing a manufacturing method of the memory device of the third embodiment;

FIG. 37 is a schematic cross-sectional view of a memory cell of a memory device of a comparative example;

FIGS. 38A and 38B are explanatory views of functions and effects of the memory device of the third embodiment;

FIG. 39 is a schematic cross-sectional view of a memory cell of a memory device of a variation of the third embodiment;

FIGS. 40A and 40B are schematic cross-sectional views of a part of the memory cell array of a memory device of a fourth embodiment;

FIG. 41 is a schematic cross-sectional view of a memory cell of the memory device of the fourth embodiment;

FIG. 42 is a schematic cross-sectional view showing a manufacturing method of the memory device of a fourth embodiment;

FIG. 43 is a schematic cross-sectional view showing a manufacturing method of the memory device of the fourth embodiment;

FIG. 44 is a schematic cross-sectional view showing a manufacturing method of the memory device of the fourth embodiment;

FIG. 45 is a schematic cross-sectional view showing a manufacturing method of the memory device of the fourth embodiment;

FIG. 46 is a schematic cross-sectional view showing a manufacturing method of the memory device of the fourth embodiment;

FIG. 47 is a schematic cross-sectional view showing a manufacturing method of the memory device of the fourth embodiment;

FIG. 48 is a schematic cross-sectional view showing a manufacturing method of the memory device of the fourth embodiment;

FIG. 49 is a schematic cross-sectional view showing a manufacturing method of the memory device of the fourth embodiment;

FIG. 50 is a schematic cross-sectional view showing a manufacturing method of the memory device of the fourth embodiment;

FIG. 51 is a schematic cross-sectional view showing a manufacturing method of the memory device of the fourth embodiment;

FIG. 52 is a schematic cross-sectional view showing a manufacturing method of the memory device of the fourth embodiment;

FIG. 53 is a schematic cross-sectional view showing a manufacturing method of the memory device of the fourth embodiment;

FIG. 54 is a schematic cross-sectional view showing a manufacturing method of the memory device of the fourth embodiment;

FIG. 55 is a block diagram of a memory device of a fifth embodiment;

FIG. 56 is an equivalent circuit diagram of a memory cell array of the memory device of the fifth embodiment; and

FIGS. 57A and 57B are schematic cross-sectional views of a part of the memory cell array of a memory device of a fifth embodiment.

### DETAILED DESCRIPTION

A memory device of an embodiment includes: a stacked body including a plurality of insulating layers and a plurality of gate electrode layers, the insulating layers and the gate electrode layers being alternately stacked in a first direction, the gate electrode layers including a first gate electrode layer and a second gate electrode layer adjacent to the first gate electrode layer in the first direction, and the insulating layers including a first insulating layer disposed between the first gate electrode layer and the second gate electrode layer; a semiconductor layer provided in the stacked body and extending in the first direction; and a gate insulating layer provided between the semiconductor layer and the first gate electrode layer, the gate insulating layer including a first region including a first oxide containing at least one of hafnium oxide or zirconium oxide, the first region including an orthorhombic crystal, and the first region containing at least one first element selected from the group consisting of carbon (C), nitrogen (N), chlorine (Cl), boron (B), hydrogen (H), fluorine (F), helium (He), and argon (Ar).

Embodiments will be described below with reference to the drawings. In the following description, identical or similar members and the like are given identical numerals, and the description of the members and the like explained once may be omitted as appropriate.

Qualitative analysis and quantitative analysis of the chemical composition of the members constituting the memory device in the present description can be conducted by, for example, secondary ion mass spectroscopy (SIMS) or energy dispersive X-ray spectroscopy (EDX). A transmission electron microscope (TEM), for example, can be used for measuring the thickness of the members constituting the memory device, the distance between the members, and the like. For example, X-ray diffraction (XRD) and nano beam diffraction (NBD) can be used for identifying the crystal system of the members constituting the memory device, comparing the degree of abundance of the crystal system, and measuring the unit cell volume.

The “ferroelectric” as used in the present description means a substance having a spontaneous polarization even without an electric field applied from outside and having the polarization reversed when an electric field is applied from outside. The “paraelectric” as used in the present description means a substance having a polarization occurring when an electric field is applied and having the polarization disappearing when the electric field is removed.

### First Embodiment

The memory device of the first embodiment includes: a stacked body including a plurality of insulating layers and a plurality of gate electrode layers, the insulating layers and the gate electrode layers being alternately stacked in a first direction, the gate electrode layers including a first gate electrode layer and a second gate electrode layer adjacent to the first gate electrode layer in the first direction, and the insulating layers including a first insulating layer disposed between the first gate electrode layer and the second gate electrode layer; a semiconductor layer provided in the stacked body and extending in the first direction; and a gate insulating layer provided between the semiconductor layer and the first gate electrode layer, the gate insulating layer including a first region including a first oxide containing at least one of hafnium oxide or zirconium oxide, the first region including an orthorhombic crystal, and the first region containing at least one first element selected from the group consisting of carbon (C), nitrogen (N), chlorine (Cl), boron (B), hydrogen (H), fluorine (F), helium (He), and argon (Ar).

The memory device of the first embodiment is a three-dimensional NAND flash memory having a memory cell transistor MT. The memory cell transistor MT includes ferroelectric in a gate insulating layer. The memory device of the first embodiment is a 3-terminal type ferroelectric memory.

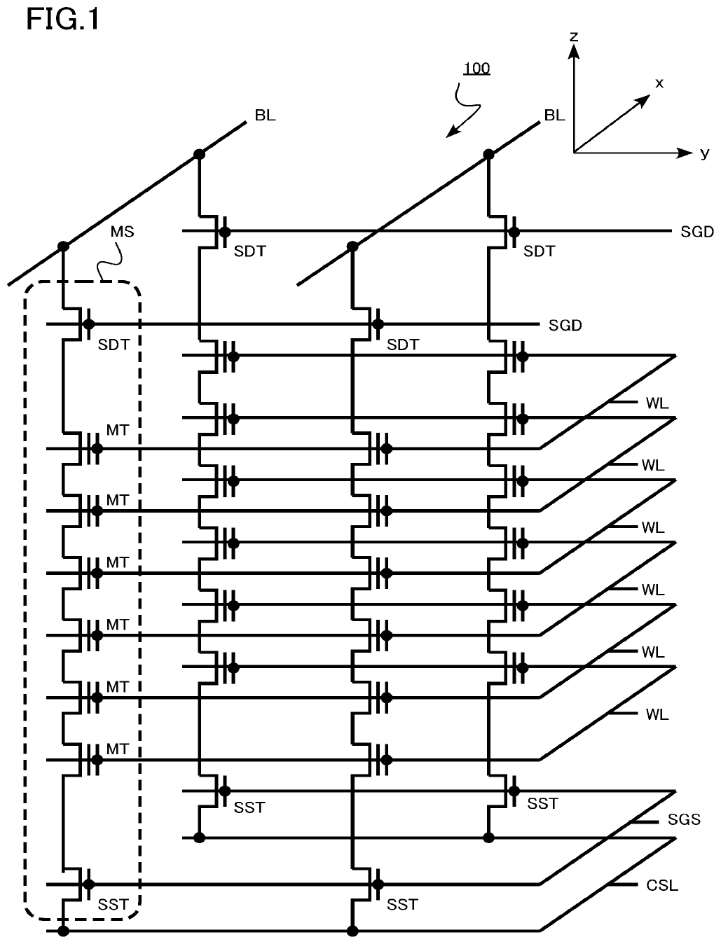

FIG. 1 is a circuit diagram of the memory cell array of the memory device according to the first embodiment.

As shown in FIG. 1, a memory cell array 100 of the three-dimensional NAND flash memory of the first embodiment includes a plurality of word lines WL, a common source line CSL, a source selection gate line SGS, a plurality of drain selection gate lines SGD, a plurality of bit lines BL, and a plurality of memory strings MS. The word line WL is an example of the gate electrode layer.

The plurality of word lines WL are stacked and disposed in the z-direction. The plurality of memory strings MS extend in the z-direction. The plurality of bit lines BL extend in the x-direction, for example.

As shown in FIG. 1, the memory string MS includes a source selection transistor SST, a plurality of the memory cell transistors MT, and a drain selection transistor SDT, which are connected in series between the common source line CSL and the bit line BL. One memory string MS is selected by the bit line BL and the drain selection gate line SGD, and one memory cell transistor MT can be selected by the word line WL. The memory cell transistor MT is a 3-terminal element.

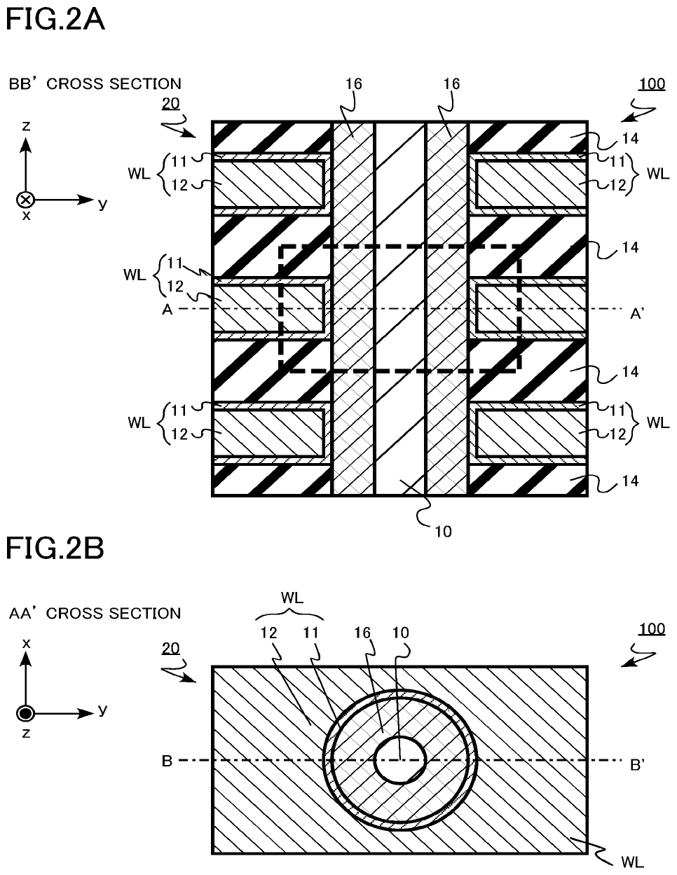

FIGS. 2A and 2B are schematic cross-sectional views of a part of the memory cell array of the memory device of the first embodiment. FIGS. 2A and 2B show a cross section of a plurality of memory cells in one memory string MS enclosed by a dotted line, for example, in the memory cell array 100 of FIG. 1.

FIG. 2A is a yz cross-sectional view of the memory cell array 100. FIG. 2A is a BB′ cross section of FIG. 2B. FIG. 2B is an xy cross-sectional view of the memory cell array 100. FIG. 2B is an AA′ cross section of FIG. 2A. In FIG. 2A, a region enclosed by a broken line is one memory cell.

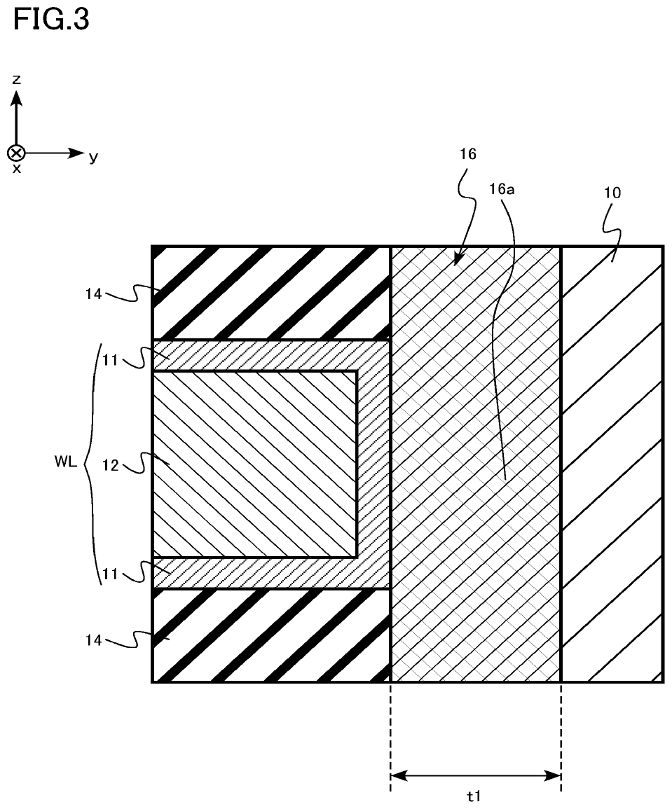

FIG. 3 is a schematic cross-sectional view of the memory cell of the memory device of the first embodiment. FIG. 3 is an enlarged cross-sectional view of a part of the memory cell. FIG. 3 is a yz cross-sectional view of the memory cell.

Hereinafter, the x-direction, y-direction, and z-direction shown in FIGS. 1, 2A, 2B, and 3 are defined as the third direction, the second direction, and the first direction, respectively. In the present description, the x-direction, y-direction, and z-direction shall include not only the orientations of the arrows in FIGS. 1, 2A, 2B, and 3 but also the orientations opposite to the arrow directions.

As shown in FIGS. 2A, 2B, and 3, the memory cell array 100 includes the plurality of word lines WL, a semiconductor layer 10, a plurality of interlayer insulating layers 14, and a gate insulating layer 16. The plurality of word lines WL and the plurality of interlayer insulating layers 14 constitute a stacked body 20.

The word line WL is an example of the gate electrode layer. The interlayer insulating layer 14 is an example of the insulating layer. Of the plurality of word lines WL, the word line WL disposed at the center in FIG. 2A is an example of the first gate electrode layer. Of the plurality of word lines WL, the word line WL disposed at the top in FIG. 2A is an example of the second gate electrode layer. In FIG. 2A, the interlayer insulating layer 14 disposed between the word line WL disposed at the center and the word line WL disposed at the top is an example of the first insulating layer.

The second gate electrode layer is adjacent to the first gate electrode layer in the z-direction. The first insulating layer is disposed between the first gate electrode layer and the second gate electrode layer.

The word line WL has, for example, a barrier metal layer 11 and a main metal layer 12. The gate insulating layer 16 has a ferroelectric region 16a. The ferroelectric region 16a is an example of the first region.

The word line WL and the interlayer insulating layer 14 are provided on a semiconductor substrate not illustrated, for example. The semiconductor substrate is, for example, a silicon substrate.

The word lines WL and the interlayer insulating layers 14 are alternately stacked on the semiconductor substrate in the z-direction. The word lines WL are disposed to be spaced apart in the z-direction. The plurality of word lines WL and the plurality of interlayer insulating layers 14 constitute a stacked body 20.

The word line WL is, for example, a plate-like conductor. The word line WL includes, for example, a metal, a metal nitride, a metal carbide, or a semiconductor. The word line WL has, for example, a barrier metal layer 11 and a main metal layer 12.

The barrier metal layer 11 is, for example, a metal nitride or a metal carbide. The barrier metal layer 11 is, for example, titanium nitride, tantalum nitride, tungsten nitride, titanium carbide, tungsten carbide, or tantalum carbide. The main metal layer 12 is, for example, a metal. The main metal layer 12 is, for example, tungsten (W), titanium (Ti), or tantalum (Ta).

The word line WL functions as a control electrode of the memory cell transistor MT. The word line WL is an example of the gate electrode layer.

The thickness of the word line WL in the z-direction is, for example, equal to or more than 5 nm and equal to or less than 40 nm.

The interlayer insulating layer 14 separates the word lines WLs. The interlayer insulating layer 14 is, for example, an oxide, an oxynitride, or a nitride. The interlayer insulating layer 14 is, for example, silicon oxide.

The thickness of the interlayer insulating layer 14 in the z-direction is, for example, equal to or more than 5 nm and equal to or less than 40 nm.

The semiconductor layer 10 is provided in the stacked body 20. The semiconductor layer 10 extends in the z-direction. The semiconductor layer 10 is provided to penetrate the stacked body 20. The semiconductor layer 10 is, for example, cylindrical.

The semiconductor layer 10 is, for example, a polycrystalline semiconductor. The semiconductor layer 10 is, for example, polycrystalline silicon. The semiconductor layer 10 functions as a channel of the memory cell transistor MT.

The conductivity type impurity concentration in the region of the semiconductor layer 10 facing the word line WL is, for example, equal to or less than 1E17 atoms/cm³.

The gate insulating layer 16 is provided between the semiconductor layer 10 and the word line WL. The gate insulating layer 16 extends in the z-direction.

The gate insulating layer 16 is provided along the side surface of the semiconductor layer 10. The gate insulating layer 16 is also provided between the semiconductor layer 10 and the interlayer insulating layer 14. The gate insulating layer 16 is provided without being divided between vertically adjacent memory cell transistors MT.

It is also possible that the gate insulating layer 16 is divided between adjacent memory cell transistors MT. That is, it is also possible that the gate insulating layer 16 is not present between the interlayer insulating layer 14 and the semiconductor layer 10.

The gate insulating layer 16 comes into contact with, for example, the semiconductor layer 10 and the word line WL. The gate insulating layer 16 includes the ferroelectric region 16a. The ferroelectric region 16a is an example of the first region. For example, the entire region of the gate insulating layer 16 may be the ferroelectric region 16a. For example, only the region of the gate insulating layer 16 facing the semiconductor layer 10 may be the ferroelectric region 16a.

The ferroelectric region 16a includes a first oxide containing at least one of hafnium oxide or zirconium oxide. The ferroelectric region 16a includes an orthorhombic crystal. The ferroelectric region 16a includes the first oxide containing at least one of an orthorhombic hafnium oxide or an orthorhombic zirconium oxide. The first oxide is ferroelectric. The first oxide is crystalline. The ferroelectric region 16a is crystalline.

The main crystal contained in the first oxide is an orthorhombic crystal. Among the crystals contained in the first oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, or triclinic crystal.

The first oxide is hafnium oxide mainly composed of orthorhombic hafnium oxide, for example. Among the crystals of hafnium oxide contained in the first oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The first oxide is zirconium oxide mainly composed of orthorhombic zirconium oxide, for example. Among the crystals of zirconium oxide contained in the first oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The first oxide may contain both hafnium (Hf) and zirconium (Zr). The atomic ratio (Zr/(Hf+Zr)) of zirconium (Zr) contained in the first oxide to the total sum of hafnium (Hf) and zirconium (Zr) contained in the first oxide is, for example, equal to or more than 50% and equal to or less than 90%. In the present description, the oxide containing hafnium (Hf) and zirconium (Zr) is called hafnium oxide if the atomic ratio (Zr/(Hf+Zr)) is less than 50%, and is called zirconium oxide if the atomic ratio is equal to or more than 50%.

The first oxide may contain both ferroelectric hafnium oxide and ferroelectric zirconium oxide. The first oxide may be a mixed crystal of, for example, ferroelectric hafnium oxide and ferroelectric zirconium oxide.

The ferroelectric region 16a contains at least one impurity element selected from the group consisting of carbon (C), nitrogen (N), chlorine (Cl), boron (B), hydrogen (H), fluorine (F), helium (He), and argon (Ar). The first oxide contains at least one impurity element selected from the group consisting of carbon (C), nitrogen (N), chlorine (Cl), boron (B), hydrogen (H), fluorine (F), helium (He), and argon (Ar). The above-described impurity element is an example of the first element.

Since the first oxide contains the above-described impurity element, it becomes possible to increase the proportion of the orthorhombic crystal in the hafnium oxide or zirconium oxide contained in the ferroelectric region 16a. Since the first oxide contains the above-described impurity element, ferroelectricity becomes likely to be expressed in the hafnium oxide or zirconium oxide contained in the ferroelectric region 16a. Since the first oxide contains the above-described impurity element, it is possible to increase spontaneous polarization of ferroelectric hafnium oxide or ferroelectric zirconium oxide.

Since the first oxide contains the above-described impurity element, the spontaneous polarization amount of the ferroelectric region 16a increases. Since the first oxide contains the above-described impurity element, the spontaneous polarization amount of the gate insulating layer 16 increases.

The concentration of the impurity element in the ferroelectric region 16a is, for example, equal to or more than 1E19 atoms/cm³ and equal to or less than 2E22 atoms/cm³. The concentration of the impurity element in the ferroelectric region 16a is, for example, equal to or more than 0.01 atomic % and equal to or less than 20 atomic %.

The unit cell volume of the orthorhombic crystal contained in the first oxide is, for example, equal to or more than 0.1340 nm³ and equal to or less than 0.1370 nm³.

The first oxide contains at least one additive element selected from the group consisting of, for example, silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). The additive element is an example of the second element.

Since the first oxide contains the above-described additive element, if the first oxide is hafnium oxide, it becomes possible to increase the proportion of the orthorhombic crystal in the hafnium oxide contained in the ferroelectric region 16a. Since the first oxide contains the above-described additive element, if the first oxide is hafnium oxide, ferroelectricity becomes likely to be expressed in the hafnium oxide contained in the ferroelectric region 16a.

The ferroelectric region 16a is composed mainly of the first oxide. Being composed mainly of the first oxide means that the mole fraction of the first oxide is the highest among the substances contained in the ferroelectric region 16a. The mole fraction of the first oxide in the ferroelectric region 16a is, for example, equal to or more than 90% and equal to or less than 100%.

The thickness of the ferroelectric region 16a in the y-direction from the word line WL toward the semiconductor layer 10 (t1 in FIG. 3) is, for example, equal to or more than 3 nm and equal to or less than 15 nm.

In the memory cell of the first embodiment, the polarization inversion state of the ferroelectric included in the ferroelectric region 16a of the gate insulating layer 16 is controlled by a voltage applied between the word line WL and the semiconductor layer 10. The threshold voltage of the memory cell transistor MT changes depending on the polarization inversion state of the ferroelectric region 16a.

When the threshold voltage of the memory cell transistor MT changes, the on-current of the memory cell transistor MT changes. For example, if a state where the threshold voltage is high and the on-current is low is defined as data “0”, and a state where the threshold voltage is low and the on-current is high is defined as data “1”, the memory cell can store 1-bit data of “0” and “1”.

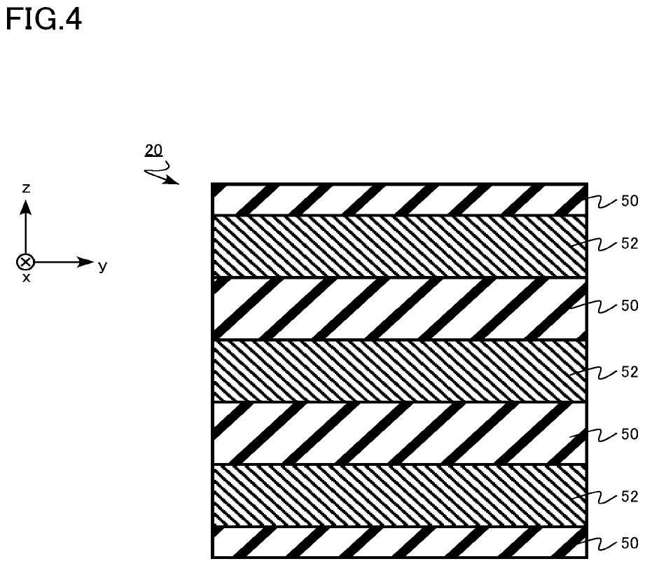

Next, an example of the manufacturing method of the memory device according to the first embodiment will be described. FIGS. 4, 5, 6, 7, 8, 9, 10, and FIG. 11 are schematic cross-sectional views showing the manufacturing method of the memory device of the first embodiment. FIGS. 4, 5, 6, 7, 8, 9, 10, and 11 each show a cross section corresponding to FIG. 2A. FIGS. 4, 5, 6, 7, 8, 9, 10, and 11 show an example of a manufacturing method of the memory cell array 100 of the memory device of the first embodiment.

First, a silicon oxide layer 50 and a silicon nitride layer 52 are alternately stacked on a semiconductor substrate not illustrated (FIG. 4). The silicon oxide layer 50 and the silicon nitride layer 52 form the stacked body 20. The silicon oxide layer 50 and the silicon nitride layer 52 are formed by, for example, a chemical vapor deposition method (CVD method). A part of the silicon oxide layer 50 eventually becomes the interlayer insulating layer 14.

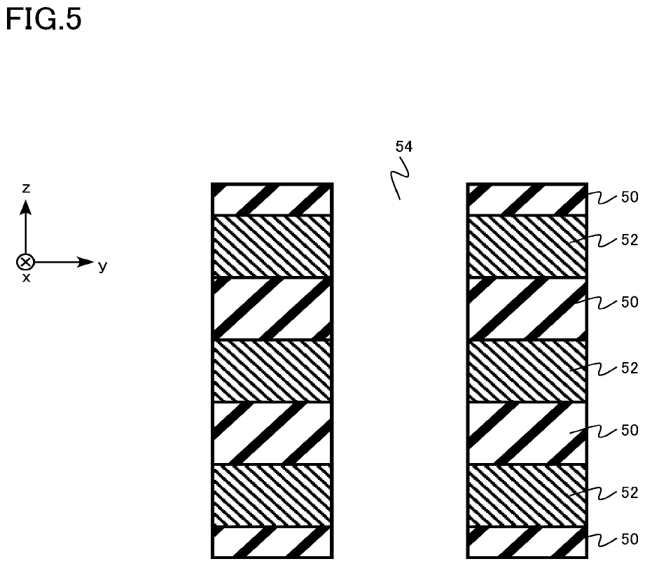

Next, an opening 54 is formed in the silicon oxide layer 50 and the silicon nitride layer 52 (FIG. 5). The opening 54 is formed by, for example, a lithography method and a reactive ion etching method (RIE method).

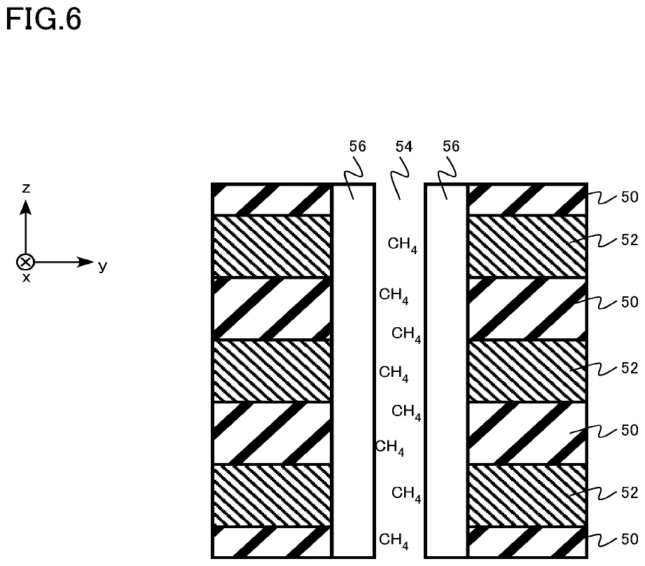

Next, on the inner surface of the opening 54, a zirconium oxide film 56 is formed (FIG. 6). The zirconium oxide film 56 contains, for example, hafnium (Hf). The zirconium oxide film 56 is formed by, for example, the atomic layer deposition method (ALD method). The zirconium oxide film 56 is amorphous. The zirconium oxide film 56 eventually becomes the gate insulating layer 16.

The film forming temperature of the zirconium oxide film 56 is, for example, equal to or higher than 150° C. and equal to or lower than 350° C.

Next, heat treatment is performed in an atmosphere containing a gas containing carbon, for example, methane gas (CH₄). When heat treatment is performed in an atmosphere containing a gas containing carbon, carbon (C) is contained as an impurity in the zirconium oxide film 56.

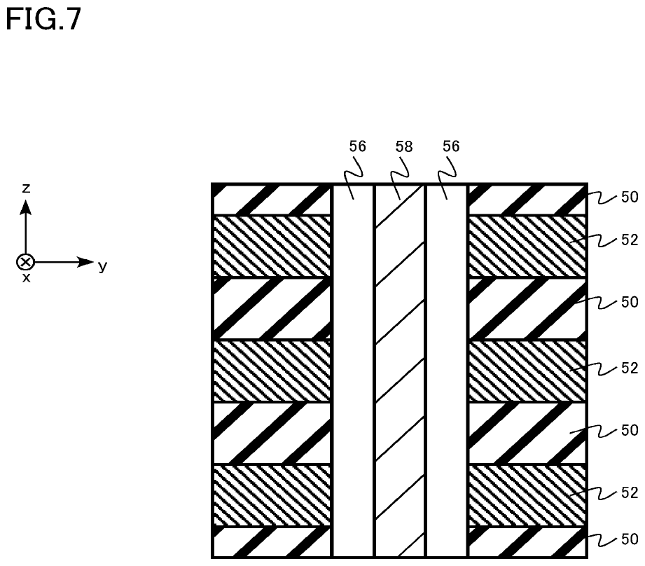

Next, an amorphous silicon film 58 is formed in the opening 54, and the opening 54 is embedded (FIG. 7). The amorphous silicon film 58 eventually becomes the semiconductor layer 10.

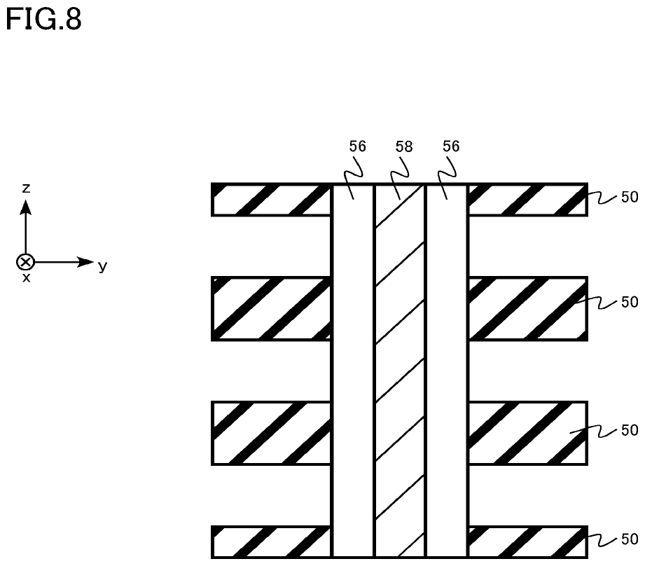

Next, the silicon nitride layer 52 is selectively removed by wet etching using an etching groove not illustrated (FIG. 8). For example, a phosphoric acid solution is used for the wet etching. The silicon nitride layer 52 is selectively etched with respect to the silicon oxide layer 50.

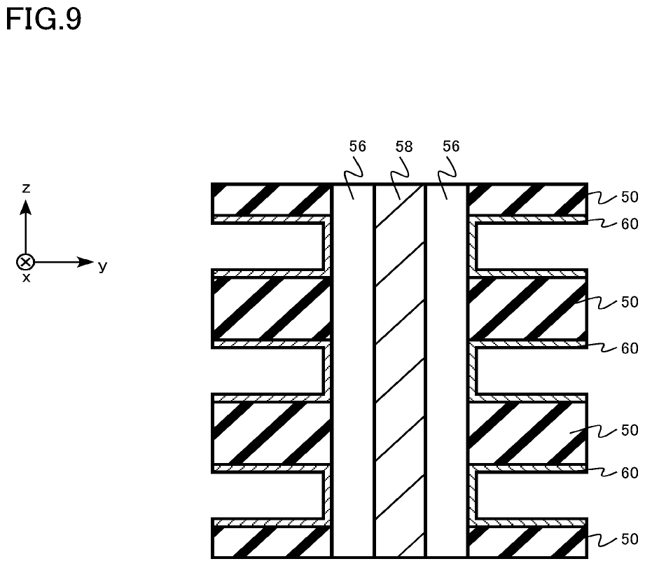

Next, a titanium nitride film 60 is formed (FIG. 9). The titanium nitride film 60 is formed, for example, by the CVD method. The titanium nitride film 60 is an example of the barrier metal layer 11.

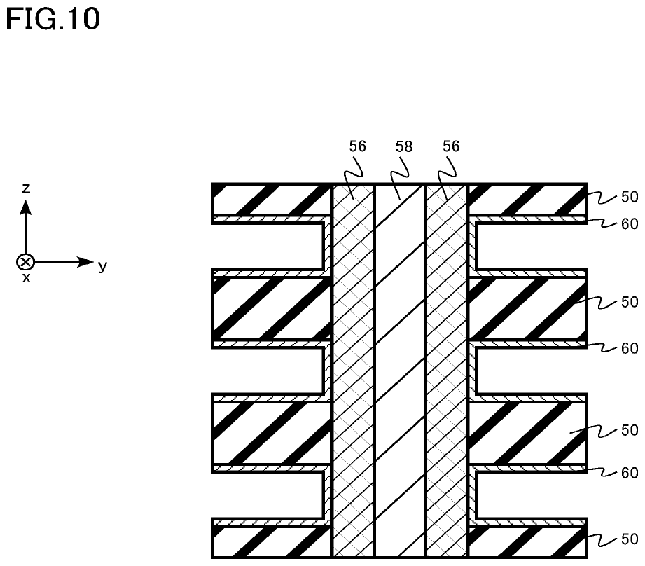

Next, crystallization annealing for crystallizing the amorphous zirconium oxide film 56 is performed (FIG. 10). By crystallization annealing, the zirconium oxide film 56 becomes ferroelectric. By crystallization annealing, an orthorhombic zirconium oxide is formed in the zirconium oxide film 56. The crystallization annealing is performed, for example, in a non-oxidizing atmosphere at a temperature of equal to or higher than 700° C. and equal to or less than 1000° C.

Due to the crystallization annealing, the amorphous silicon film 58 is also crystallized to become a polycrystalline silicon film.

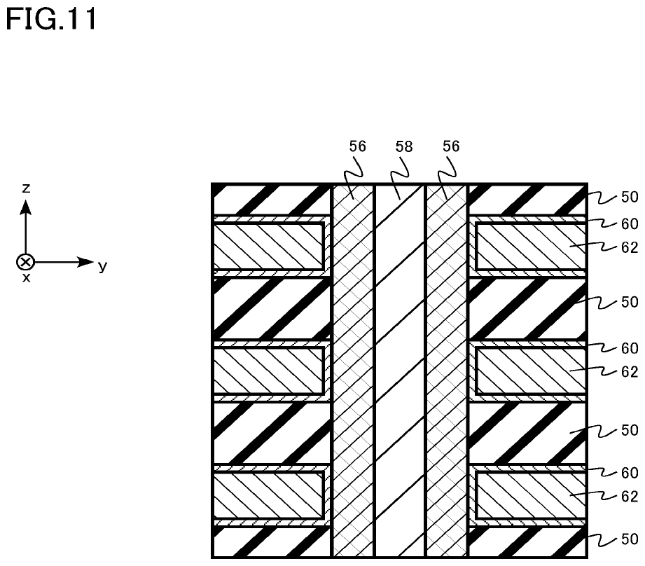

Next, a tungsten film 62 is formed on the titanium nitride film 60 (FIG. 11). The tungsten film 62 is formed, for example, by the CVD method. The tungsten film 62 is an example of the main metal layer 12.

By the above-described manufacturing method, the memory cell array 100 of the memory device of the first embodiment is manufactured.

Next, the functions and effects of the memory device of the first embodiment will be described.

In a 3-terminal type ferroelectric memory such as the three-dimensional NAND flash memory of the first embodiment, the polarization inversion state of a gate insulating layer of the memory cell transistor is controlled by a voltage applied between the gate electrode and the semiconductor layer. The threshold voltage of the memory cell transistor changes depending on the polarization inversion state of the gate insulating layer.

When the threshold voltage of the memory cell transistor changes, the on-current of the memory cell transistor changes. For example, if a state where the threshold voltage is high and the on-current is low is defined as data “0”, and a state where the threshold voltage is low and the on-current is high is defined as data “1”, the memory cell can store 1-bit data of “0” and “1”. In a 3-terminal type ferroelectric memory, it is desired to enlarge the difference between the threshold voltage in the state where the on-current is low and the threshold voltage in the state where the on-current is high, i.e., the so-called memory window.

Enlarging the memory window stabilizes the operation of the ferroelectric memory, for example. Enlarging the memory window makes it easy to provide a multivalued memory cell of the ferroelectric memory, for example.

In the three-dimensional NAND flash memory of the first embodiment, the gate insulating layer 16 includes the first oxide containing at least one of an orthorhombic hafnium oxide or an orthorhombic zirconium oxide. Then, the first oxide contains at least any one impurity element selected from the group consisting of carbon (C), nitrogen (N), chlorine (Cl), boron (B), hydrogen (H), fluorine (F), helium (He), and argon (Ar). Since the gate insulating layer 16 includes the first oxide containing the impurity element described above, the memory window of the three-dimensional NAND flash memory can be enlarged. The details will be described below.

The inventors have found that spontaneous polarization of ferroelectric hafnium oxide or ferroelectric zirconium oxide increases when the ferroelectric hafnium oxide or the ferroelectric zirconium oxide contains at least one impurity element selected from the group consisting of carbon (C), nitrogen (N), chlorine (Cl), boron (B), hydrogen (H), fluorine (F), helium (He), and argon (Ar). The inventors have also found that the unit cell volume of the ferroelectric hafnium oxide or the ferroelectric zirconium oxide increases by increasing the concentration of the above-described impurity element contained in the ferroelectric hafnium oxide or the ferroelectric zirconium oxide. The crystal of ferroelectric hafnium oxides and the crystal of ferroelectric zirconium oxides are orthorhombic.

The unit cell volume of the ferroelectric hafnium oxide or the ferroelectric zirconium oxide is considered to increase by including the interstitial impurity element.

The polarization inversion of ferroelectric hafnium oxide or ferroelectric zirconium oxide is caused by the position change of an oxygen atom in the crystal. The spontaneous polarization of ferroelectrics is considered to increase with an increase in the position change of the oxygen atom in the crystal. It is considered that as the unit cell volume of ferroelectric hafnium oxide or ferroelectric zirconium oxide increases, the position change of the oxygen atom in the crystal increases, and the spontaneous polarization of the ferroelectric increases.

The inventors have found that when amorphous hafnium oxide or amorphous zirconium oxide contains the above-described impurity element, the proportion of the orthorhombic crystal in the hafnium oxide or zirconium oxide increases after crystallization. This is considered to be because the above-described impurity element suppresses the formation of monoclinic crystal, which is more stable than orthorhombic crystal.

In particular, in the case of hafnium oxide or zirconium oxide having a chemical composition crystallizing at a relatively low temperature, formation of monoclinic is likely to proceed by heat treatment prior to crystallization annealing, for example. Therefore, the proportion of monoclinic in hafnium oxide or zirconium oxide after the crystallization annealing possibly increases. The heat treatment prior to crystallization annealing is, for example, formation of an amorphous silicon film to be the semiconductor layer 10.

Since the amorphous hafnium oxide or the amorphous zirconium oxide contains the impurity element, the formation of the monoclinic is suppressed. Therefore, it is possible to reduce the proportion of monoclinic in hafnium oxide or zirconium oxide after the crystallization annealing.

Since the amorphous hafnium oxide or the amorphous zirconium oxide contains the impurity element, the formation of the monoclinic is suppressed, which is considered to be because the crystallization temperature of the amorphous hafnium oxide or the amorphous zirconium oxide rises.

When the proportion of orthorhombic crystal in hafnium oxide or zirconium oxide increases, the proportion of ferroelectrics in hafnium oxide or zirconium oxide increases. Therefore, the spontaneous polarization amount of hafnium oxide or zirconium oxide increases.

According to the three-dimensional NAND flash memory of the first embodiment, the gate insulating layer 16 contains at least one of orthorhombic hafnium oxide or orthorhombic zirconium oxide, and also includes the first oxide containing the impurity element described above. Therefore, the spontaneous polarization of ferroelectric hafnium oxide or ferroelectric zirconium oxide increases, and the proportion of the ferroelectric in the gate insulating layer 16 also increases. Therefore, the spontaneous polarization amount of the gate insulating layer 16 increases. Hence, it is possible to enlarge the memory window of the three-dimensional NAND flash memory of the first embodiment.

The concentration of the impurity element in the ferroelectric region 16a is preferably equal to or more than 1E19 atoms/cm³ and equal to or less than 2E22 atoms/cm³, and more preferably equal to or more than 1E20 atoms/cm³ and equal to or less than 2E21 atoms/cm³. By exceeding the above-described lower limit value, the spontaneous polarization amount of the gate insulating layer 16 increases. By falling below the upper limit value, the gate leakage current via the state due to the impurity element decreases.

The unit cell volume of the orthorhombic crystal contained in the first oxide is preferably equal to or more than 0.1340 nm³, and more preferably equal to or more than 0.1345 nm³. By exceeding the above-described lower limit value, the spontaneous polarization amount of the gate insulating layer 16 increases.

The unit cell volume of the orthorhombic hafnium oxide and the orthorhombic zirconium oxide that do not contain the above-described impurity element is less than 0.1340 nm³.

The above-described impurity element contained in the first oxide is preferably carbon (C) in particular from the viewpoint of raising the crystallization temperature of hafnium oxide or zirconium oxide. The above-described impurity element contained in the first oxide is preferably nitrogen (N) from the viewpoint of inactivating the state caused by oxygen deficiency in hafnium oxide or zirconium oxide and suppressing the gate leakage current. The above-described impurity element contained in the first oxide is preferably hydrogen (H) from the viewpoint of introducing the impurity element into hafnium oxide or zirconium oxide at a high concentration. The above-described impurity element contained in the first oxide is preferably fluorine (F) from the viewpoint that it has high combination energy in hafnium oxide or zirconium oxide and can stably exist in hafnium oxide or zirconium oxide. The above-described impurity element contained in the first oxide is preferably helium (He) or argon (Ar) from the viewpoint that a combination state is not formed in hafnium oxide or zirconium oxide and the formation of the state causing generation of the gate leakage current can be suppressed.

The first oxide is preferably zirconium oxide from the viewpoint of increasing the spontaneous polarization amount of the gate insulating layer 16.

The atomic ratio (Zr/(Hf+Zr)) of zirconium (Zr) contained in the first oxide to the total sum of hafnium (Hf) and zirconium (Zr) contained in the first oxide is preferably equal to or more than 50% and equal to or less 90%, and more preferably equal to or more than 65% and equal to or less than 75%. By exceeding the above-described lower limit value, the spontaneous polarization amount of the gate insulating layer 16 can be increased.

By lowering the atomic ratio (Zr/(Hf+Zr)), the dielectric constant of the first oxide is lowered, and it is possible to increase the equivalent oxide thickness (EOT), which is the thickness of the silicon oxide film required to achieve the same capacitance as the gate insulating layer 16. The atomic ratio (Zr/(Hf+Zr)) is preferably equal to or less than 75% from the viewpoint of thickening the EOT of the gate insulating layer 16.

By raising the atomic ratio (Zr/(Hf+Zr)), the dielectric constant of the first oxide is raised, and it is possible to decrease the equivalent oxide thickness (EOT) converted into the silicon oxide film of the gate insulating layer 16. The atomic ratio (Zr/(Hf+Zr)) is preferably equal to or less than 65% from the viewpoint of thinning the EOT of the gate insulating layer 16.

The crystallization temperature of zirconium oxide is lower than that of, for example, hafnium oxide. Therefore, monoclinic is likely to be formed. Therefore, adding the above-mentioned impurity element is particularly effective from the viewpoint of increasing the spontaneous polarization amount of zirconium oxide.

If the first oxide is hafnium oxide, the first oxide preferably contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). Since hafnium oxide contains the above-mentioned additive element, ferroelectricity becomes likely to be expressed in the hafnium oxide.

If the first oxide is hafnium oxide, the first oxide preferably includes, in particular, zirconium (Zr), yttrium (Y), or lanthanum (La) as an additive element. Hafnium oxide containing zirconium (Zr), yttrium (Y), or lanthanum (La) has a lower crystallization temperature than that containing another additive element. Therefore, monoclinic is likely to be formed in hafnium oxide. Therefore, adding the above-mentioned impurity element to hafnium oxide is particularly effective from the viewpoint of increasing the spontaneous polarization amount of hafnium oxide.

(Variation)

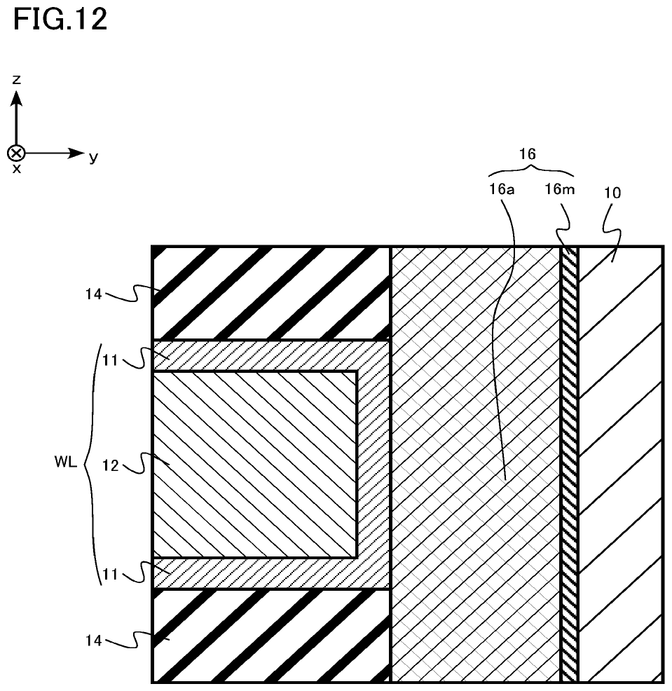

FIG. 12 is a schematic cross-sectional view of the memory cell of the memory device of the variation of the first embodiment. FIG. 12 is a yz cross-sectional view of the memory cell.

The three-dimensional NAND flash memory of the variation of the first embodiment is different from the three-dimensional NAND flash memory of the first embodiment in that the gate insulating layer 16 includes an interfacial insulating film 16m. The interfacial insulating film 16m is disposed between the ferroelectric region 16a and the semiconductor layer 10.

The interfacial insulating film 16m is in contact with the ferroelectric region 16a. The interfacial insulating film 16m is in contact with the semiconductor layer 10.

The interfacial insulating film 16m is, for example, a paraelectric film. The interfacial insulating film 16m is, for example, a silicon oxide film.

In the memory cell of the variation of the first embodiment, since the gate insulating layer 16 includes the interfacial insulating film 16m, the interface state between, for example, the gate insulating layer 16 and the semiconductor layer 10 decreases. Therefore, the mobility of the memory cell transistor MT, for example, is improved.

Thus, according to the first embodiment and its variation, since the gate insulating layer includes the first oxide containing an impurity element, a memory device having a large memory window can be achieved.

### Second Embodiment

The memory device of the second embodiment includes: a stacked body including a plurality of insulating layers and a plurality of gate electrode layers, the insulating layers and the gate electrode layers alternately stacked in a first direction, the gate electrode layers including a first gate electrode layer and a second gate electrode layer adjacent to the first gate electrode layer in the first direction, and the insulating layers including a first insulating layer disposed between the first gate electrode layer and the second gate electrode layer; a semiconductor layer provided in the stacked body and extending in the first direction; and a gate insulating layer provided between the semiconductor layer and the first gate electrode layer, the gate insulating layer including a first region and a second region, the first region including a first oxide containing at least one of hafnium oxide or zirconium oxide, the first region including an orthorhombic crystal, the second region being disposed between the first region and the first gate electrode layer, and the second region including a first insulator having a chemical composition different from a chemical composition of the first oxide. The memory device of the second embodiment is different from the memory device of the first embodiment in that the first oxide does not contain an impurity element and that the gate insulating layer includes a second region. Hereinafter, part of description of the contents overlapping the first embodiment may be omitted.

The memory device of the second embodiment is a three-dimensional NAND flash memory having a memory cell transistor MT. The memory cell transistor MT includes ferroelectric in a gate insulating layer. The memory device of the second embodiment is a 3-terminal type ferroelectric memory.

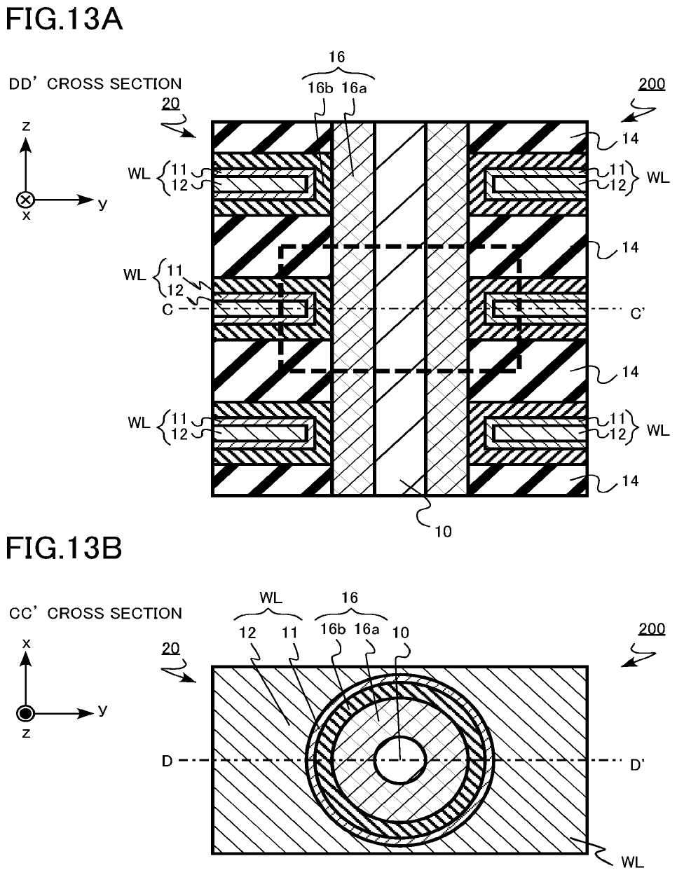

FIGS. 13A and 13B are schematic cross-sectional views of a part of the memory cell array of the memory device of the second embodiment. FIGS. 13A and 13B show a cross section of a plurality of memory cells in a memory cell array 200.

FIG. 13A is a yz cross-sectional view of the memory cell array 200. FIG. 13A is a DD′ cross section of FIG. 13B. FIG. 13B is an xy cross-sectional view of the memory cell array 200. FIG. 13B is a CC′ cross section of FIG. 13A. In FIG. 13A, a region enclosed by a broken line is one memory cell.

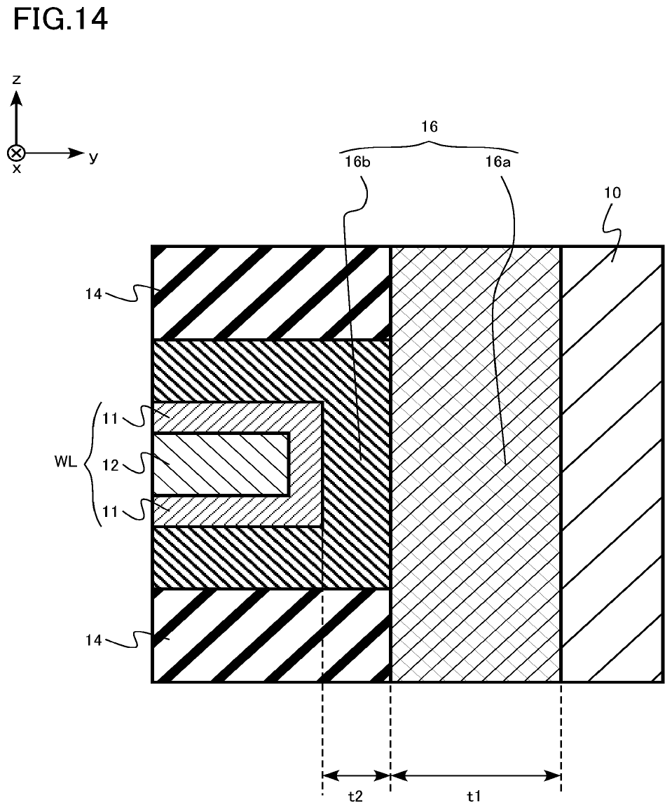

FIG. 14 is a schematic cross-sectional view of the memory cell of the memory device of the second embodiment. FIG. 14 is an enlarged cross-sectional view of a part of the memory cell. FIG. 14 is a yz cross-sectional view of the memory cell.

Hereinafter, the x-direction, y-direction, and z-direction shown in FIGS. 13A, 13B, and 14 are defined as the third direction, the second direction, and the first direction, respectively. In the present description, the x-direction, y-direction, and z-direction shall include not only the orientations of the arrows in FIGS. 13A, 13B, and 14 but also the orientations opposite to the arrow directions.

As shown in FIGS. 13A and 13B, the memory cell array 200 includes the plurality of word lines WL, a semiconductor layer 10, a plurality of interlayer insulating layers 14, and a gate insulating layer 16. The plurality of word lines WL and the plurality of interlayer insulating layers 14 constitute a stacked body 20.

The word line WL is an example of the gate electrode layer. The interlayer insulating layer 14 is an example of the insulating layer. Of the plurality of word lines WL, the word line WL disposed at the center in FIG. 13A is an example of the first gate electrode layer. Of the plurality of word lines WL, the word line WL disposed at the top in FIG. 13A is an example of the second gate electrode layer. In FIG. 13A, the interlayer insulating layer 14 disposed between the word line WL disposed at the center and the word line WL disposed at the top is an example of the first insulating layer.

The second gate electrode layer is adjacent to the first gate electrode layer in the z-direction. The first insulating layer is disposed between the first gate electrode layer and the second gate electrode layer.

The word line WL has, for example, a barrier metal layer 11 and a main metal layer 12. The gate insulating layer 16 has a ferroelectric region 16a and a paraelectric region 16b. The ferroelectric region 16a is an example of the first region. The paraelectric region 16b is an example of the second region.

The word line WL and the interlayer insulating layer 14 are provided on a semiconductor substrate not illustrated, for example. The semiconductor substrate is, for example, a silicon substrate.

The word lines WL and the interlayer insulating layers 14 are alternately stacked on the semiconductor substrate in the z-direction. The word lines WL are disposed to be spaced apart in the z-direction. The plurality of word lines WL and the plurality of interlayer insulating layers 14 constitute a stacked body 20.

The word line WL is, for example, a plate-like conductor. The word line WL includes, for example, a metal, a metal nitride, a metal carbide, or a semiconductor. The word line WL has, for example, a barrier metal layer 11 and a main metal layer 12.

The barrier metal layer 11 is, for example, a metal nitride or a metal carbide. The barrier metal layer 11 is, for example, titanium nitride, tantalum nitride, tungsten nitride, titanium carbide, tungsten carbide, or tantalum carbide. The main metal layer 12 is, for example, a metal. The main metal layer 12 is, for example, tungsten (W), titanium (Ti), or tantalum (Ta).

The word line WL functions as a control electrode of the memory cell transistor MT. The word line WL is an example of the gate electrode layer.

The thickness of the word line WL in the z-direction is, for example, equal to or more than 5 nm and equal to or less than 40 nm.

The interlayer insulating layer 14 separates the word lines WLs. The interlayer insulating layer 14 is, for example, an oxide, an oxynitride, or a nitride. The interlayer insulating layer 14 is, for example, silicon oxide.

The thickness of the interlayer insulating layer 14 in the z-direction is, for example, equal to or more than 5 nm and equal to or less than 40 nm.

The semiconductor layer 10 is provided in the stacked body 20. The semiconductor layer 10 extends in the z-direction. The semiconductor layer 10 is provided to penetrate the stacked body 20. The semiconductor layer 10 is, for example, cylindrical.

The semiconductor layer 10 is, for example, a polycrystalline semiconductor. The semiconductor layer 10 is, for example, polycrystalline silicon. The semiconductor layer 10 functions as a channel of the memory cell transistor MT.

The gate insulating layer 16 is provided between the semiconductor layer 10 and the word line WL. The gate insulating layer 16 extends in the z-direction.

The gate insulating layer 16 is provided along the side surface of the semiconductor layer 10. The gate insulating layer 16 is also provided between the semiconductor layer 10 and the interlayer insulating layer 14. The gate insulating layer 16 is provided without being divided between adjacent memory cell transistors MT.

It is also possible that the gate insulating layer 16 is divided between adjacent memory cell transistors MT. That is, it is also possible that the gate insulating layer 16 is not present between the interlayer insulating layer 14 and the semiconductor layer 10.

The gate insulating layer 16 comes into contact with, for example, the semiconductor layer 10 and the word line WL. The gate insulating layer 16 includes the ferroelectric region 16a and the paraelectric region 16b.

The ferroelectric region 16a includes a first oxide containing at least one of hafnium oxide or zirconium oxide. The ferroelectric region 16a contains orthorhombic crystal. The ferroelectric region 16a includes the first oxide containing at least one of an orthorhombic hafnium oxide or an orthorhombic zirconium oxide. The first oxide is ferroelectric. The first oxide is crystalline. The ferroelectric region 16a is crystalline.

The main crystal contained in the first oxide is an orthorhombic crystal. Among the crystals contained in the first oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, or triclinic crystal.

The first oxide is hafnium oxide mainly composed of orthorhombic hafnium oxide, for example. Among the crystals of hafnium oxide contained in the first oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The first oxide is zirconium oxide mainly composed of orthorhombic zirconium oxide, for example. Among the crystals of zirconium oxide contained in the first oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The first oxide may contain both hafnium (Hf) and zirconium (Zr). The atomic ratio (Zr/(Hf+Zr)) of zirconium (Zr) contained in the first oxide to the total sum of hafnium (Hf) and zirconium (Zr) contained in the first oxide is equal to or more than 50% and equal to or less than 90%. In the present description, the oxide containing hafnium (Hf) and zirconium (Zr) is called hafnium oxide if the atomic ratio (Zr/(Hf+Zr)) is less than 50%, and is called zirconium oxide if the atomic ratio is equal to or more than 50%.

The first oxide may contain both ferroelectric hafnium oxide and ferroelectric zirconium oxide. The first oxide may be a mixed crystal of, for example, ferroelectric hafnium oxide and ferroelectric zirconium oxide.

The first oxide contains at least one additive element selected from the group consisting of, for example, silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr).

Since the first oxide contains the above-described additive element, if the first oxide is hafnium oxide, it becomes possible to increase the proportion of the orthorhombic crystal in the hafnium oxide contained in the ferroelectric region 16a. Since the first oxide contains the above-described additive element, if the first oxide is hafnium oxide, ferroelectricity becomes likely to be expressed in the hafnium oxide contained in the ferroelectric region 16a.

The ferroelectric region 16a is composed mainly of the first oxide. Being composed mainly of the first oxide means that the mole fraction of the first oxide is the highest among the substances contained in the ferroelectric region 16a. The mole fraction of the first oxide is, for example, equal to or more than 90% and equal to or less than 100%.

The thickness of the ferroelectric region 16a in the y-direction from the word line WL toward the semiconductor layer 10 (t1 in FIG. 14) is, for example, equal to or more than 3 nm and equal to or less than 15 nm.

The paraelectric region 16b is disposed between the ferroelectric region 16a and the word line WL. The paraelectric region 16b includes a first insulator having a chemical composition different from that of the first oxide.

The paraelectric region 16b is not provided between the interlayer insulating layer 14 and the ferroelectric region 16a.

The first insulator is paraelectric. The first insulator is amorphous or crystalline. The paraelectric region 16b is amorphous or crystalline.

If the first insulator is crystalline, the main crystal contained in the first insulator is, for example, a crystal other than orthorhombic crystal. The crystals other than the orthorhombic crystal are cubic crystal, hexagonal crystal, tetragonal crystal, monoclinic crystal, or triclinic crystal.

The first insulator is an oxide, a nitride, or an oxynitride. The first insulator is, for example, silicon oxide, aluminum oxide, yttrium oxide, or titanium oxide. The first insulator is, for example, aluminum oxide or zirconium oxide other than orthorhombic crystal. The first insulator is hafnium oxide containing at least any one element selected from the group consisting of, for example, silicon (Si), aluminum (Al), yttrium (Y), zirconium (Zr), and lanthanum (La).

The first insulator is, for example, silicon nitride or aluminum nitride. The first insulator is, for example, silicon oxynitride.

The paraelectric region 16b is composed mainly of the first insulator. Being composed mainly of the first insulator means that the mole fraction of the first insulator is the highest among the substances contained in the paraelectric region 16b. The mole fraction of the first insulator is, for example, equal to or more than 90% and equal to or less than 100%.

The thickness (t2 in FIG. 14) of the paraelectric region 16b in the y-direction from the word line WL toward the semiconductor layer 10 is thinner than the thickness (t1 in FIG. 14) of the ferroelectric region 16a in the y-direction from the word line WL toward the semiconductor layer 10. The thickness (t2 in FIG. 14) of the paraelectric region 16b in the y-direction is, for example, equal to or more than 0.5 nm and equal to or less than 15 nm.

In the memory cell of the second embodiment, the polarization inversion state of the ferroelectric included in the ferroelectric region 16a of the gate insulating layer 16 is controlled by a voltage applied between the word line WL and the semiconductor layer 10. The threshold voltage of the memory cell transistor MT changes depending on the polarization inversion state of the ferroelectric region 16a.

When the threshold voltage of the memory cell transistor MT changes, the on-current of the memory cell transistor MT changes. For example, if a state where the threshold voltage is high and the on-current is low is defined as data “0”, and a state where the threshold voltage is low and the on-current is high is defined as data “1”, the memory cell can store 1-bit data of “0” and “1”.

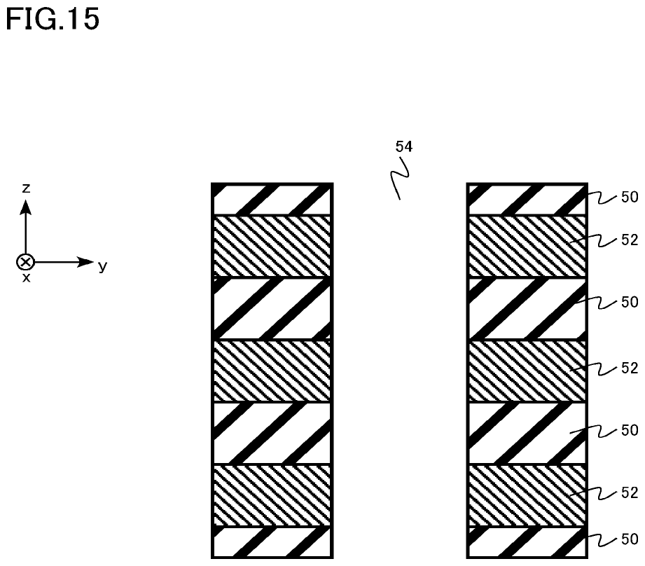

Next, an example of the manufacturing method of the memory device according to the second embodiment will be described. FIGS. 15, 16, 17, 18, 19, 20, 21, and 22 are schematic cross-sectional views showing the manufacturing method of the memory device of the second embodiment. FIGS. 14, 15, 16, 17, 18, 19, 20, 21, and 22 each show a cross section corresponding to FIG. 13A. FIGS. 14, 15, 16, 17, 18, 19, 20, 21, and 22 show an example of a manufacturing method of the memory cell array 200 of the memory device of the second embodiment.

The manufacturing method of the memory device of the second embodiment is the same as that of the first embodiment until the opening 54 is formed in the silicon oxide layer 50 and the silicon nitride layer 52 (FIG. 15).

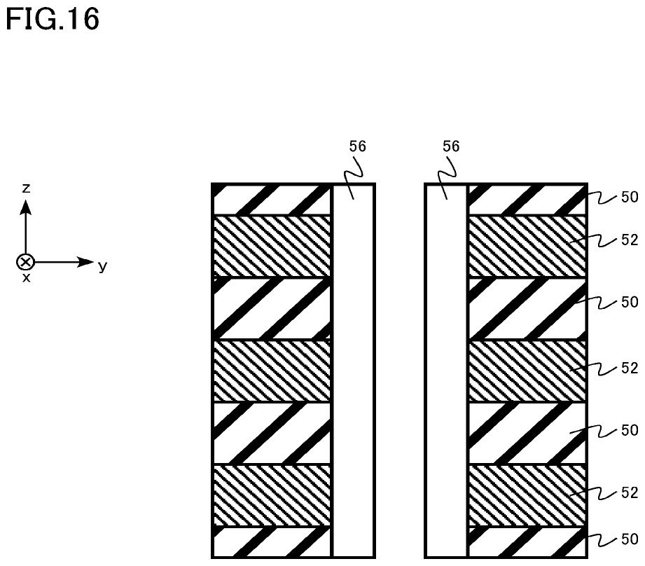

Next, on the inner surface of the opening 54, a zirconium oxide film 56 is formed (FIG. 16). The zirconium oxide film 56 contains, for example, hafnium (Hf). The zirconium oxide film 56 is formed by, for example, the ALD method. The zirconium oxide film 56 is amorphous. The zirconium oxide film 56 eventually becomes the ferroelectric region 16a of the gate insulating layer 16.

The film forming temperature of the zirconium oxide film 56 is, for example, equal to or higher than 150° C. and equal to or lower than 350° C.

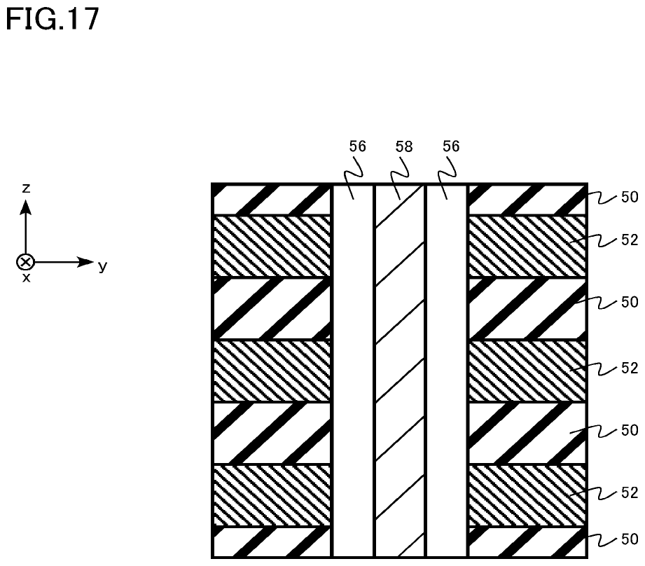

Next, an amorphous silicon film 58 is formed in the opening 54, and the opening 54 is embedded (FIG. 17). The amorphous silicon film 58 eventually becomes the semiconductor layer 10.

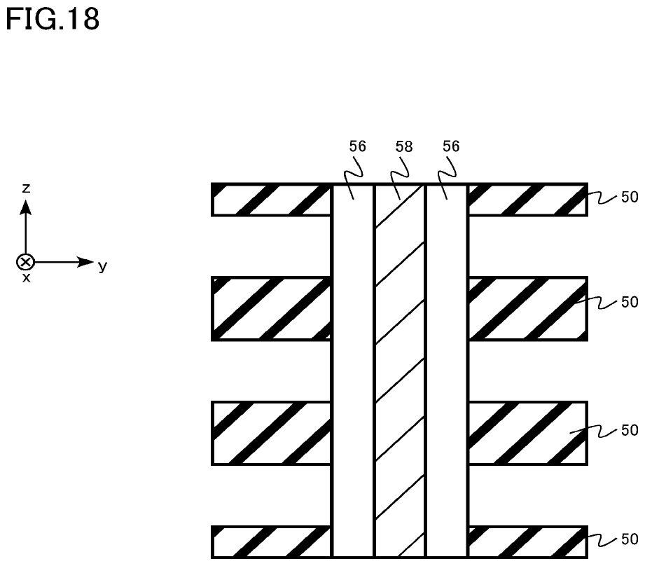

Next, the silicon nitride layer 52 is selectively removed by wet etching using an etching groove not illustrated (FIG. 18). For wet etching, for example, by using a phosphoric acid solution, the silicon nitride layer 52 is selectively etched with respect to the silicon oxide layer 50.

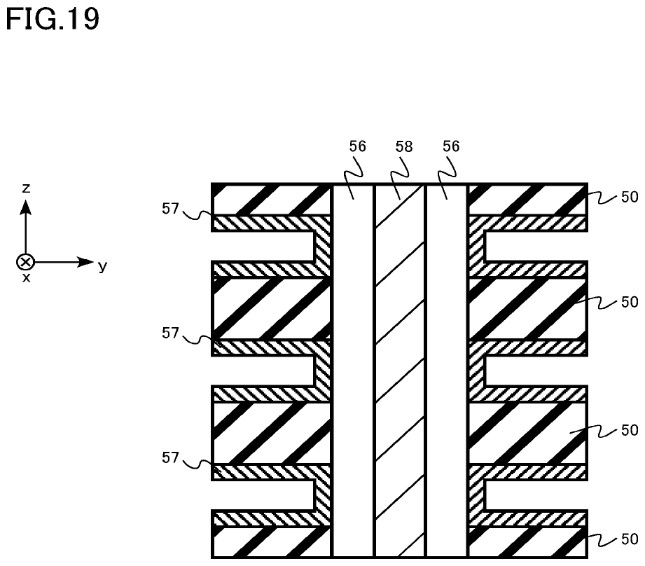

Next, a hafnium oxide film 57 is formed (FIG. 19). The hafnium oxide film 57 contains, for example, aluminum (Al). The atomic ratio (Al/(Hf+Al)) of aluminum (Al) contained in the hafnium oxide film 57 to the total sum of hafnium (Hf) and aluminum (Al) contained in the hafnium oxide film 57 is, for example, equal to or more than 5%.

The hafnium oxide film 57 is formed by, for example, the ALD method. The hafnium oxide film 57 is amorphous. The hafnium oxide film 57 eventually becomes the paraelectric region 16b of the gate insulating layer 16.

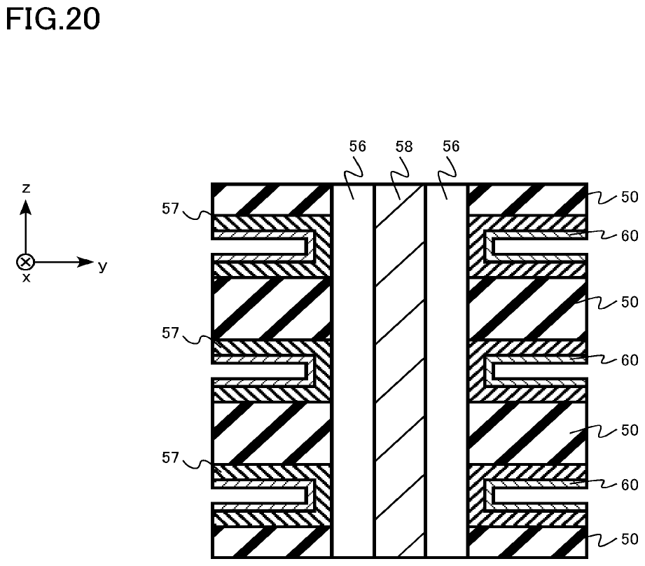

Next, a titanium nitride film 60 is formed (FIG. 20). The titanium nitride film 60 is formed, for example, by the CVD method. The titanium nitride film 60 is an example of the barrier metal layer 11.

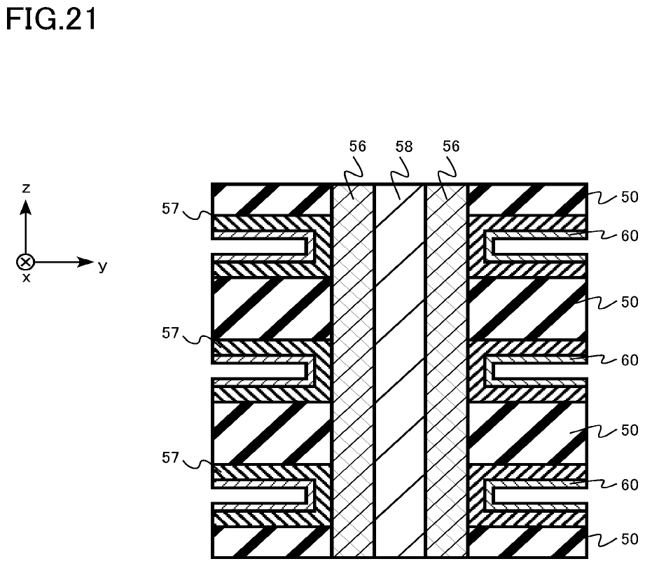

Next, crystallization annealing for crystallizing the amorphous zirconium oxide film 56 is performed (FIG. 21). By crystallization annealing, the zirconium oxide film 56 becomes ferroelectric. By crystallization annealing, an orthorhombic zirconium oxide is formed in the zirconium oxide film 56.

By crystallization annealing, the hafnium oxide film 57 becomes crystalline. Since the hafnium oxide film 57 contains equal to or more than 5% of aluminum (Al), the hafnium oxide film 57 does not become ferroelectric but becomes paraelectric. For example, a monoclinic hafnium oxide is formed on the hafnium oxide film 57.

The crystallization annealing is performed, for example, in a non-oxidizing atmosphere at a temperature of equal to or higher than 700° C. and equal to or less than 1000° C.

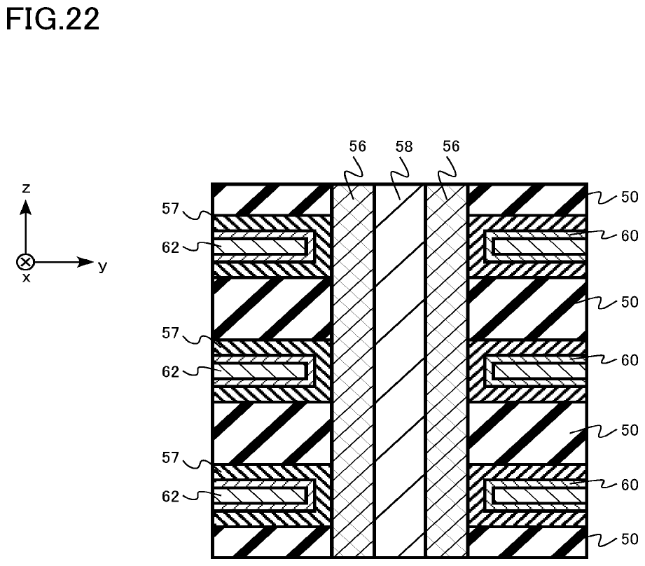

Next, a tungsten film 62 is formed on the titanium nitride film 60 (FIG. 22). The tungsten film 62 is formed, for example, by the CVD method. The tungsten film 62 is an example of the main metal layer 12.

By the above-described manufacturing method, the memory cell array 200 of the memory device of the second embodiment is manufactured.

Next, the functions and effects of the memory device of the second embodiment will be described.

In a 3-terminal type ferroelectric memory such as the three-dimensional NAND flash memory of the second embodiment, the polarization inversion state of a gate insulating layer of the memory cell transistor is controlled by a voltage applied between the gate electrode and the semiconductor layer. The threshold voltage of the memory cell transistor changes depending on the polarization inversion state of the gate insulating layer.

When the threshold voltage of the memory cell transistor changes, the on-current of the memory cell transistor changes. For example, if a state where the threshold voltage is high and the on-current is low is defined as data “0”, and a state where the threshold voltage is low and the on-current is high is defined as data “1”, the memory cell can store 1-bit data of “0” and “1”. In a 3-terminal type ferroelectric memory, it is desired to enlarge the difference between the threshold voltage in the state where the on-current is low and the threshold voltage in the state where the on-current is high, i.e., the so-called memory window.

Enlarging the memory window stabilizes the operation of the ferroelectric memory, for example. Enlarging the memory window makes it easy to provide a multivalued memory cell of the ferroelectric memory, for example.

In the three-dimensional NAND flash memory of the second embodiment, the gate insulating layer 16 includes the ferroelectric region 16a and the paraelectric region 16b. The paraelectric region 16b is disposed between the ferroelectric region 16a and the word line WL.

The gate insulating layer 16 includes, on the side of the word line WL, the paraelectric region 16b not reversing polarization. Thus, polarization charges are unevenly distributed on the side of the semiconductor layer 10 in the word line WL. Therefore, the dominant force of the polarization charge to the electric potential of the semiconductor layer 10 is improved. Therefore, it becomes possible to enlarge the memory window of the three-dimensional NAND flash memory.

From the viewpoint of enlarging the memory window, thickness (t2 in FIG. 14) of the paraelectric region 16b in the y-direction from the word line WL toward the semiconductor layer 10 is preferably equal to or more than 0.5 nm, more preferably equal to or more than 1 nm, and yet more preferably equal to or more than 2 nm.

From the viewpoint of optimizing the size of the memory window and the magnitude of the gate voltage applied to the word line WL, the thickness (t2 in FIG. 14) of the paraelectric region 16b in the y-direction from the word line WL toward the semiconductor layer 10 is preferably thinner than the thickness (t1 in FIG. 14) of the ferroelectric region 16a in the y-direction from the word line WL toward the semiconductor layer 10.

From the viewpoint of reducing the thickness t2 of the paraelectric region 16b, the dielectric constant of the first insulator included in the paraelectric region 16b is preferably lower than the dielectric constant of the first oxide included in the ferroelectric region 16a. The first insulator is preferably, for example, a silicon oxide or an aluminum oxide.

From the viewpoint of reducing the gate voltage applied to the word line WL, the dielectric constant of the first insulator included in the paraelectric region 16b is preferably higher than the dielectric constant of the first oxide included in the ferroelectric region 16a.

From the viewpoint of equalizing the electric fields applied to the paraelectric region 16b and the ferroelectric region 16a and improving the reliability of the memory cell, the dielectric constant of the first insulator included in the paraelectric region 16b is preferably equal to the dielectric constant of the first oxide included in the ferroelectric region 16a. The first insulator is preferably, for example, paraelectric hafnium oxide or paraelectric zirconium oxide. The first insulator is preferably, for example, hafnium oxide other than the orthorhombic crystal or zirconium oxide other than the orthorhombic crystal.

From the viewpoint of suppressing the diffusion of metal atoms from the word line WL and improving the reliability of the memory cell, the first insulator included in the paraelectric region 16b is preferably a nitride. The first insulator is preferably, for example, silicon nitride or aluminum nitride.

The first oxide is preferably zirconium oxide from the viewpoint of increasing the spontaneous polarization amount of the gate insulating layer 16.

The atomic ratio (Zr/(Hf+Zr)) of zirconium (Zr) contained in the first oxide to the total sum of hafnium (Hf) and zirconium (Zr) contained in the first oxide is preferably equal to or more than 50% and equal to or less 90%, and more preferably equal to or more than 65% and equal to or less than 75%. By exceeding the above-described lower limit value, the spontaneous polarization amount of the gate insulating layer 16 can be increased.

By lowering the atomic ratio (Zr/(Hf+Zr)), the dielectric constant of the first oxide is lowered, and it is possible to increase the EOT converted into the silicon oxide film of the gate insulating layer 16. The atomic ratio (Zr/(Hf+Zr)) is preferably equal to or less than 75% from the viewpoint of thickening the EOT of the gate insulating layer 16.

By raising the atomic ratio (Zr/(Hf+Zr)), the dielectric constant of the first oxide is raised, and it is possible to decrease the equivalent oxide thickness (EOT) converted into the silicon oxide film of the gate insulating layer 16. The atomic ratio (Zr/(Hf+Zr)) is preferably equal to or less than 65% from the viewpoint of thinning the EOT of the gate insulating layer 16.

If the first oxide is hafnium oxide, the first oxide preferably contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). Since hafnium oxide contains the above-mentioned additive element, ferroelectricity becomes likely to be expressed in the hafnium oxide.

(Variation)

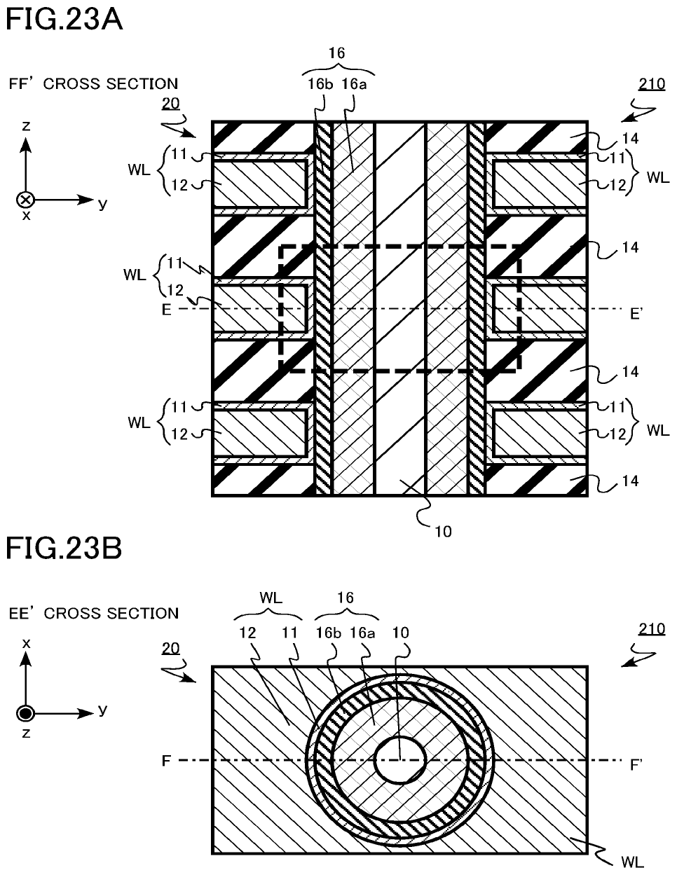

FIGS. 23A and 23B are schematic cross-sectional views of a part of the memory cell array of the memory device of the variation of the second embodiment. FIGS. 23A and 23B show a cross section of a plurality of memory cells in a memory cell array 210.

FIG. 23A is a yz cross-sectional view of the memory cell array 210. FIG. 23A is an FF′ cross section of FIG. 23B. FIG. 23B is an xy cross-sectional view of the memory cell array 210. FIG. 23B is an EE′ cross section of FIG. 23A. In FIG. 23A, a region enclosed by a broken line is one memory cell.

The three-dimensional NAND flash memory of the variation of the second embodiment is different from the three-dimensional NAND flash memory of the first embodiment in that the paraelectric region 16b is also provided between the interlayer insulating layer 14 and the ferroelectric region 16a.

Thus, according to the second embodiment and its variation, since the gate insulating layer includes the paraelectric region between the ferroelectric region and the gate electrode layer, a memory device having a large memory window can be achieved.

### Third Embodiment

The memory device of the third embodiment includes: a stacked body including a plurality of insulating layers and a plurality of gate electrode layers, the insulating layers and the gate electrode layers alternately stacked in a first direction, the gate electrode layers including a first gate electrode layer and a second gate electrode layer adjacent to the first gate electrode layer in the first direction, the insulating layers including a first insulating layer disposed between the first gate electrode layer and the second gate electrode layer, and the first insulating layer including a first insulator; a semiconductor layer provided in the stacked body and extending in the first direction; a gate insulating layer provided between the semiconductor layer and the first gate electrode layer, the gate insulating layer including a first region including a first oxide containing at least one of hafnium oxide or zirconium oxide, and the first region including an orthorhombic crystal; and an intermediate insulating layer provided between the semiconductor layer and the first insulating layer, the intermediate insulating layer including a second oxide containing at least one of hafnium oxide or zirconium oxide, and the second oxide having a dielectric constant higher than a dielectric constant of the first insulator. A thickness of the gate insulating layer in a second direction from the first gate electrode layer toward the semiconductor layer is thicker than a thickness of the intermediate insulating layer in the second direction. The memory device of the third embodiment is different from the memory device of the first embodiment in that the first oxide does not contain an impurity element and that the first oxide includes an intermediate insulating layer. Hereinafter, part of description of the contents overlapping the first embodiment will be omitted.

The memory device of the third embodiment is a three-dimensional NAND flash memory having a memory cell transistor MT. The memory cell transistor MT includes ferroelectric in a gate insulating layer. The memory device of the first embodiment is a 3-terminal type ferroelectric memory.

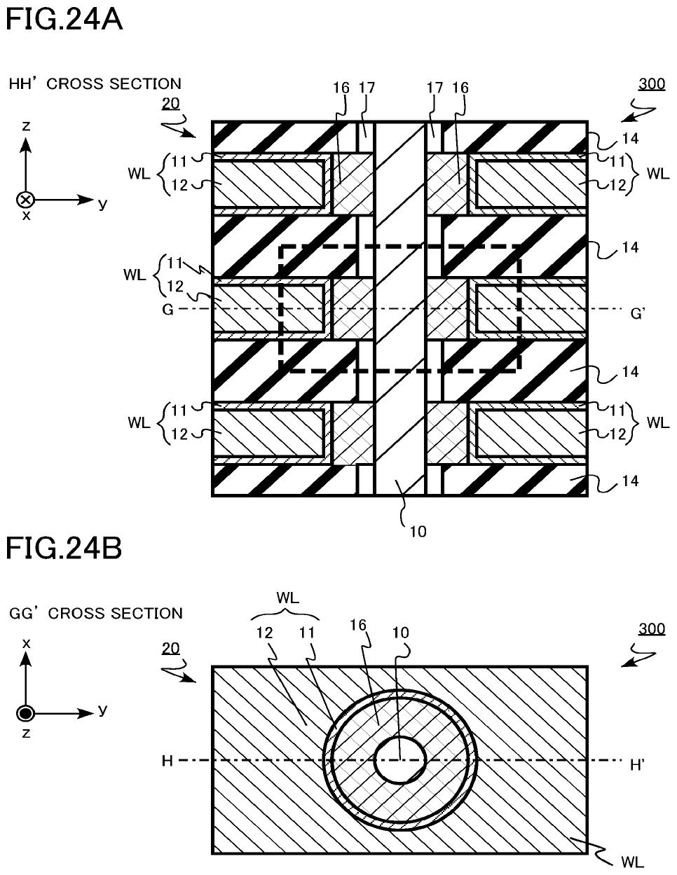

FIGS. 24A and 24B are schematic cross-sectional views of a part of the memory cell array of the memory device of the third embodiment. FIGS. 24A and 24B show a cross section of a plurality of memory cells in a memory cell array 300.

FIG. 24A is a yz cross-sectional view of the memory cell array 300. FIG. 24A is an HH′ cross section of FIG. 24B. FIG. 24B is an xy cross-sectional view of the memory cell array 300. FIG. 24B is a GG′ cross section of FIG. 24A. In FIG. 24A, a region enclosed by a broken line is one memory cell.

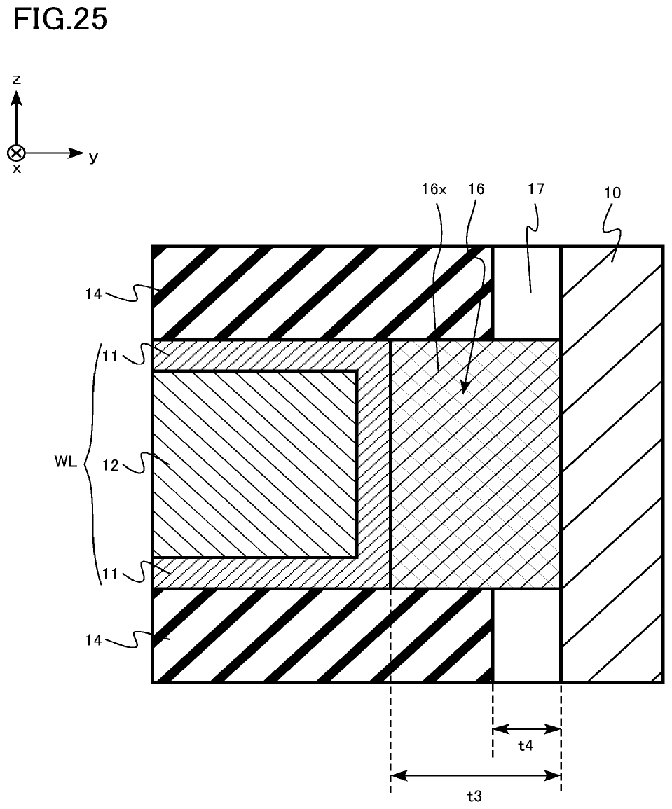

FIG. 25 is a schematic cross-sectional view of the memory cell of the memory device of the third embodiment. FIG. 25 is an enlarged cross-sectional view of a part of the memory cell. FIG. 25 is a yz cross-sectional view of the memory cell.

Hereinafter, the x-direction, y-direction, and z-direction shown in FIGS. 24A, 24B, and 25 are defined as the third direction, the second direction, and the first direction, respectively. In the present description, the x-direction, y-direction, and z-direction shall include not only the orientations of the arrows in FIGS. 24A, 24B, and 25 but also the orientations opposite to the arrow directions.

As shown in FIGS. 24A and 24B, the memory cell array 300 includes the plurality of word lines WL, a semiconductor layer 10, a plurality of interlayer insulating layers 14, a gate insulating layer 16, and an intermediate insulating layer 17. The plurality of word lines WL and the plurality of interlayer insulating layers 14 constitute a stacked body 20.

The word line WL is an example of the gate electrode layer. The interlayer insulating layer 14 is an example of the insulating layer. Of the plurality of word lines WL, the word line WL disposed at the center in FIG. 24A is an example of the first gate electrode layer. Of the plurality of word lines WL, the word line WL disposed at the top in FIG. 24A is an example of the second gate electrode layer. In FIG. 24A, the interlayer insulating layer 14 disposed between the word line WL disposed at the center and the word line WL disposed at the top is an example of the first insulating layer.

The second gate electrode layer is adjacent to the first gate electrode layer in the z-direction. The first insulating layer is disposed between the first gate electrode layer and the second gate electrode layer.

The word line WL has, for example, a barrier metal layer 11 and a main metal layer 12. The gate insulating layer 16 has a first ferroelectric region 16x. The first ferroelectric region 16x is an example of the first region.

The word line WL and the interlayer insulating layer 14 are provided on a semiconductor substrate not illustrated, for example. The semiconductor substrate is, for example, a silicon substrate.

The word lines WL and the interlayer insulating layers 14 are alternately stacked on the semiconductor substrate in the z-direction. The word lines WL are disposed to be spaced apart in the z-direction. The plurality of word lines WL and the plurality of interlayer insulating layers 14 constitute a stacked body 20.

The word line WL is, for example, a plate-like conductor. The word line WL includes, for example, a metal, a metal nitride, a metal carbide, or a semiconductor. The word line WL has, for example, a barrier metal layer 11 and a main metal layer 12.

The barrier metal layer 11 is, for example, a metal nitride or a metal carbide. The barrier metal layer 11 is, for example, titanium nitride, tantalum nitride, tungsten nitride, titanium carbide, tungsten carbide, or tantalum carbide. The main metal layer 12 is, for example, a metal. The main metal layer 12 is, for example, tungsten (W), titanium (Ti), or tantalum (Ta).

The word line WL functions as a control electrode of the memory cell transistor MT. The word line WL is an example of the gate electrode layer.

The thickness of the word line WL in the z-direction is, for example, equal to or more than 5 nm and equal to or less than 40 nm.

The interlayer insulating layer 14 separates the word lines WLs. The interlayer insulating layer 14 includes a first insulator. The first insulator is, for example, an oxide, an oxynitride, or a nitride. The first insulator is, for example, silicon oxide.

The interlayer insulating layer 14 is composed mainly of the first insulator. Being composed mainly of the first insulator means that the mole fraction of the first insulator is the highest among the substances contained in the interlayer insulating layer 14. The mole fraction of the first insulator is, for example, equal to or more than 90% and equal to or less than 100%. The interlayer insulating layer 14 is, for example, silicon oxide.

The thickness of the interlayer insulating layer 14 in the z-direction is, for example, equal to or more than 5 nm and equal to or less than 40 nm.

The semiconductor layer 10 is provided in the stacked body 20. The semiconductor layer 10 extends in the z-direction. The semiconductor layer 10 is provided to penetrate the stacked body 20. The semiconductor layer 10 is, for example, cylindrical.

The semiconductor layer 10 is, for example, a polycrystalline semiconductor. The semiconductor layer 10 is, for example, polycrystalline silicon. The semiconductor layer 10 functions as a channel of the memory cell transistor MT.

The gate insulating layer 16 is provided between the semiconductor layer 10 and the word line WL. The gate insulating layer 16 is divided between adjacent memory cell transistors MT.

The gate insulating layer 16 comes into contact with, for example, the semiconductor layer 10 and the word line WL. The gate insulating layer 16 includes the first ferroelectric region 16x. For example, the entire region of the gate insulating layer 16 may be the first ferroelectric region 16x. For example, only the region of the gate insulating layer 16 facing the semiconductor layer 10 may be the first ferroelectric region 16x.

The first ferroelectric region 16x includes a first oxide containing at least one of hafnium oxide or zirconium oxide. The first ferroelectric region 16x contains orthorhombic crystal. The first ferroelectric region 16x includes the first oxide containing at least one of an orthorhombic hafnium oxide or an orthorhombic zirconium oxide. The first oxide is ferroelectric. The first oxide is crystalline. The first ferroelectric region 16x is crystalline.

The main crystal contained in the first oxide is an orthorhombic crystal. Among the crystals contained in the first oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, and triclinic crystal.

The first oxide is hafnium oxide mainly composed of orthorhombic hafnium oxide, for example. Among the crystals of hafnium oxide contained in the first oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The first oxide is zirconium oxide mainly composed of orthorhombic zirconium oxide, for example. Among the crystals of zirconium oxide contained in the first oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The first oxide may contain both hafnium (Hf) and zirconium (Zr). The atomic ratio (Zr/(Hf+Zr)) of zirconium (Zr) contained in the first oxide to the total sum of hafnium (Hf) and zirconium (Zr) contained in the first oxide is, for example, equal to or more than 50% and equal to or less than 90%. In the present description, the oxide containing hafnium (Hf) and zirconium (Zr) is called hafnium oxide if the atomic ratio (Zr/(Hf+Zr)) is less than 50%, and is called zirconium oxide if the atomic ratio is equal to or more than 50%.

The first oxide may contain both ferroelectric hafnium oxide and ferroelectric zirconium oxide. The first oxide may be a mixed crystal of, for example, ferroelectric hafnium oxide and ferroelectric zirconium oxide.

The first oxide contains at least one additive element selected from the group consisting of, for example, silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr).

Since the first oxide contains the above-described additive element, if the first oxide is hafnium oxide, it becomes possible to increase the proportion of the orthorhombic crystal in the hafnium oxide contained in the first ferroelectric region 16x. Since the first oxide contains the above-described additive element, if the first oxide is hafnium oxide, ferroelectricity becomes likely to be expressed in the hafnium oxide contained in the first ferroelectric region 16x.

The first ferroelectric region 16x is composed mainly of the first oxide. Being composed mainly of the first oxide means that the mole fraction of the first oxide is the highest among the substances contained in the first ferroelectric region 16x. The mole fraction of the first oxide is, for example, equal to or more than 90%.

The thickness of the first ferroelectric region 16x in the y-direction from the word line WL toward the semiconductor layer 10 (t3 in FIG. 25) is, for example, equal to or more than 3 nm and equal to or less than 15 nm. The thickness (t3 in FIG. 25) of the gate insulating layer 16 in the y-direction from the word line WL toward the semiconductor layer 10 is, for example, equal to or more than 3 nm and equal to or less than 15 nm.

The intermediate insulating layer 17 is provided between the semiconductor layer 10 and the interlayer insulating layer 14. The intermediate insulating layer 17 includes a second oxide containing at least one of hafnium oxide or zirconium oxide. The second oxide is, for example, paraelectric. The second oxide is amorphous or crystalline. The intermediate insulating layer 17 is, for example, amorphous or crystalline.

For example, if the second oxide is crystalline, the second oxide contains a crystal other than orthorhombic crystal. If the second oxide is crystalline, the main crystal contained in the second oxide is, for example, a crystal other than orthorhombic crystal. The crystals other than the orthorhombic crystal are cubic crystal, hexagonal crystal, tetragonal crystal, monoclinic crystal, or triclinic crystal.

The dielectric constant of the second oxide is higher than the dielectric constant of the first insulator included in the interlayer insulating layer 14.

For example, the first oxide included in the first ferroelectric region 16x and the second oxide included in the intermediate insulating layer 17 have the identical chemical composition.

The intermediate insulating layer 17 is composed mainly of the second oxide. Being composed mainly of the second oxide means that the mole fraction of the second oxide is the highest among the substances contained in the intermediate insulating layer 17. The mole fraction of the second oxide is, for example, equal to or more than 90% and equal to or less than 100%.

The thickness (t3 in FIG. 25) of the gate insulating layer 16 in the y-direction from the word line WL toward the semiconductor layer 10 is thicker than the thickness (t4 in FIG. 25) of the intermediate insulating layer 17 in the y-direction from the word line WL toward the semiconductor layer 10. The thickness t3 of the gate insulating layer 16 in the y-direction from the word line WL toward the semiconductor layer 10 is equal to or larger than 1.2 times and equal to or smaller than 5 times the thickness t4 of the intermediate insulating layer 17 in the y-direction from the word line WL toward the semiconductor layer 10, for example. The thickness t4 of the intermediate insulating layer 17 in the y-direction is, for example, equal to or more than 0.5 nm and equal to or less than 15 nm.

In the memory cell of the third embodiment, the polarization inversion state of the ferroelectric included in the first ferroelectric region 16x of the gate insulating layer 16 is controlled by a voltage applied between the word line WL and the semiconductor layer 10. The threshold voltage of the memory cell transistor MT changes depending on the polarization inversion state of the first ferroelectric region 16x.

When the threshold voltage of the memory cell transistor MT changes, the on-current of the memory cell transistor MT changes. For example, if a state where the threshold voltage is high and the on-current is low is defined as data “0”, and a state where the threshold voltage is low and the on-current is high is defined as data “1”, the memory cell can store 1-bit data of “0” and “1”.

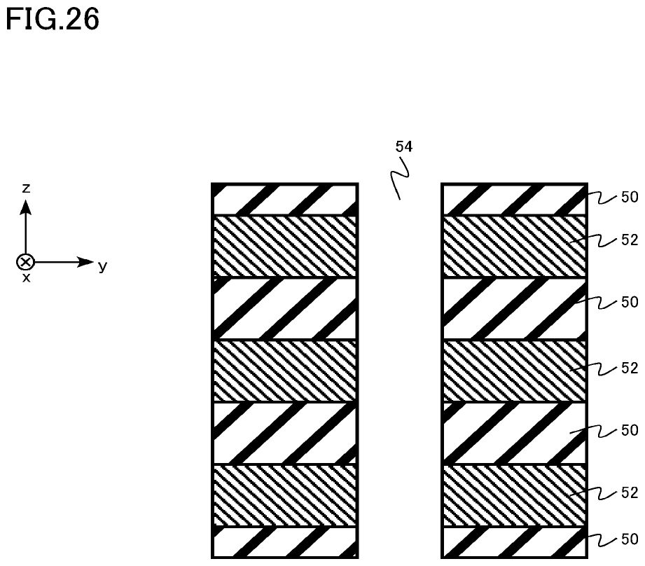

Next, an example of the manufacturing method of the memory device according to the third embodiment will be described. FIGS. 26, 27, 28, 29, 30, 31, 32, 33, 34, 35, and 36 are schematic cross-sectional views showing the manufacturing method of the memory device of the third embodiment. FIGS. 26, 27, 28, 29, 30, 31, 32, 33, 34, 35, and 36 each show a cross section corresponding to FIG. 24A. FIGS. 26, 27, 28, 29, 30, 31, 32, 33, 34, 35, and 36 show an example of a manufacturing method of the memory cell array 300 of the memory device of the third embodiment.

The manufacturing method of the memory device of the third embodiment is the same as that of the first embodiment until the opening 54 is formed in the silicon oxide layer 50 and the silicon nitride layer 52 (FIG. 26).

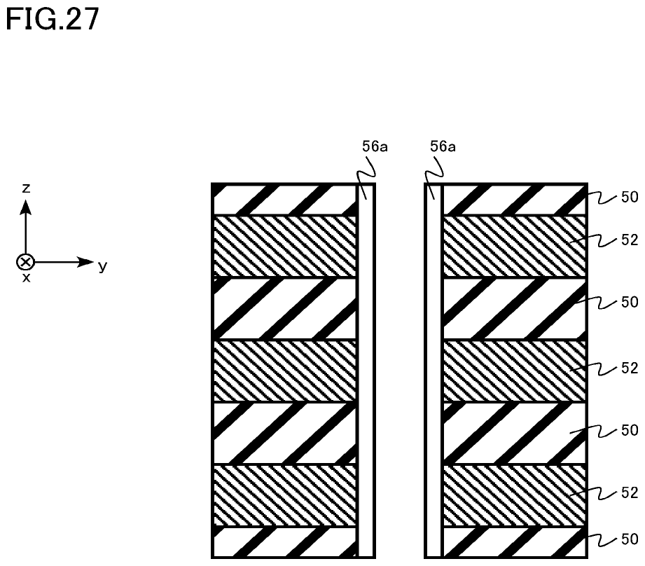

Next, on the inner surface of the opening 54, a first zirconium oxide film 56a is formed (FIG. 27). The first zirconium oxide film 56a contains, for example, hafnium (Hf). The first zirconium oxide film 56a is formed by, for example, the ALD method. The first zirconium oxide film 56a is amorphous. The first zirconium oxide film 56a eventually becomes a part of the gate insulating layer 16 and the intermediate insulating layer 17.

The film forming temperature of the first zirconium oxide film 56a is, for example, equal to or higher than 150° C. and equal to or lower than 350° C. The film thickness of the first zirconium oxide film 56a is, for example, equal to or less than 8 nm.

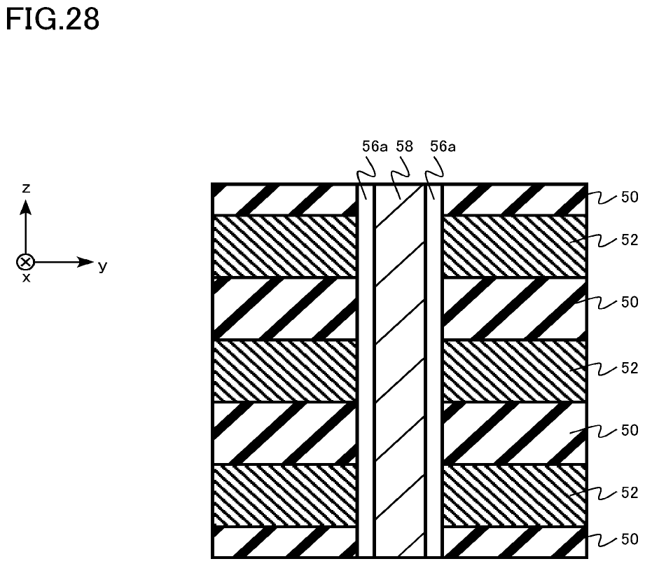

Next, an amorphous silicon film 58 is formed in the opening 54, and the opening 54 is embedded (FIG. 28). The amorphous silicon film 58 eventually becomes the semiconductor layer 10.

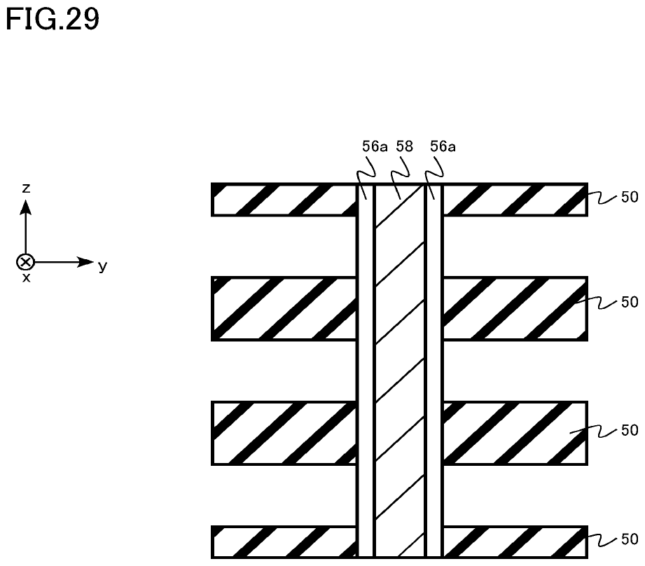

Next, the silicon nitride layer 52 is selectively removed by wet etching using an etching groove not illustrated (FIG. 29). For wet etching, for example, by using a phosphoric acid solution, the silicon nitride layer 52 is selectively etched with respect to the silicon oxide layer 50.

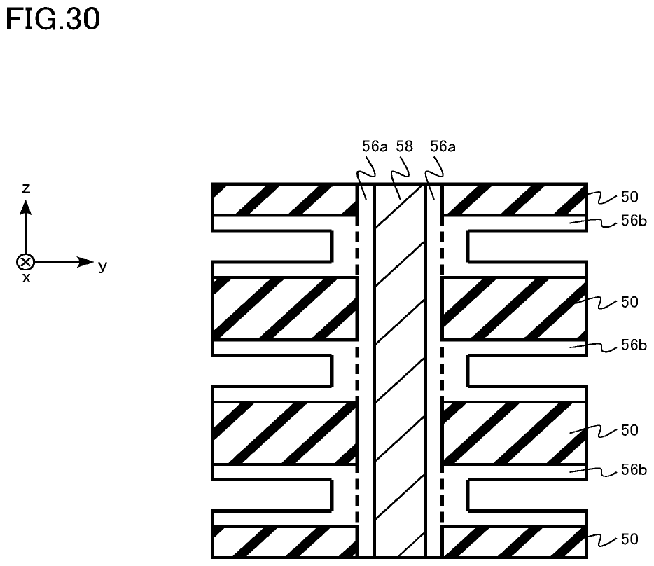

Next, a second zirconium oxide film 56b is formed (FIG. 30). The second zirconium oxide film 56b contains, for example, hafnium (Hf). The second zirconium oxide film 56b is formed by, for example, the ALD method. The second zirconium oxide film 56b is amorphous. A part of the second zirconium oxide film 56b eventually becomes a part of the gate insulating layer 16.

The film forming temperature of the second zirconium oxide film 56b is, for example, equal to or higher than 150° C. and equal to or lower than 350° C. The film thickness of the second zirconium oxide film 56b is, for example, equal to or greater than 2 nm.

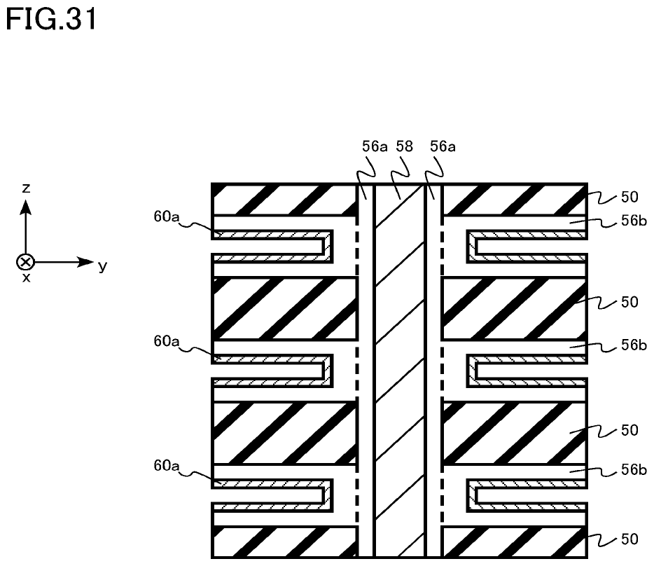

Next, a first titanium nitride film 60a is formed (FIG. 31). The first titanium nitride film 60a is formed, for example, by the CVD method.

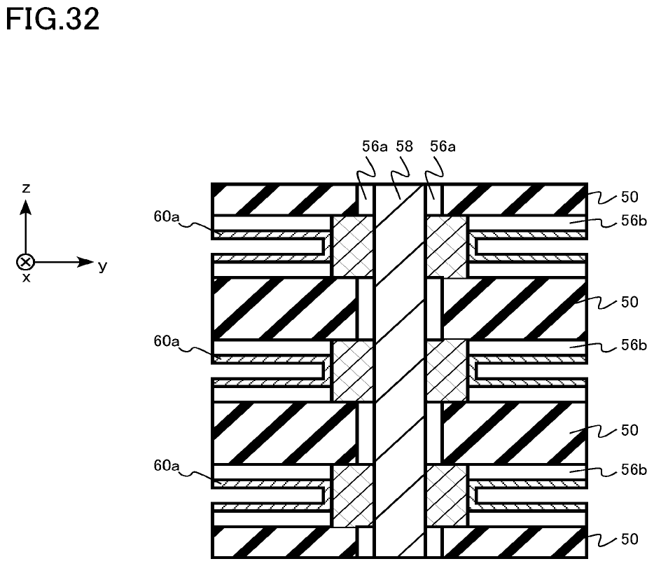

Next, crystallization annealing is performed to crystallize a part of the first zirconium oxide film 56a of amorphous and the second zirconium oxide film 56b of amorphous (FIG. 32). By crystallization annealing, the first zirconium oxide film 56a held between the first titanium nitride film 60a and the amorphous silicon film 58 is crystallized into ferroelectric. By crystallization annealing, the second zirconium oxide film 56b held between the first titanium nitride film 60a and the amorphous silicon film 58 is crystallized into ferroelectric. By crystallization annealing, an orthorhombic zirconium oxide is formed in a part of the first zirconium oxide film 56a and the second zirconium oxide film 56b.

In crystallization annealing, the first zirconium oxide film 56a between the silicon oxide layer 50 and the amorphous silicon film 58 is thin in film thickness, and hence crystallization does not proceed and the first zirconium oxide film 56a remains in an amorphous state. The first zirconium oxide film 56a between the silicon oxide layer 50 and the amorphous silicon film 58 eventually becomes the intermediate insulating layer 17.

In crystallization annealing, the second zirconium oxide film 56b between the first titanium nitride film 60a and the silicon oxide layer 50 is thin in film thickness, and hence crystallization does not proceed and the second zirconium oxide film 56b remains in an amorphous state.

The crystallization annealing is performed, for example, in a non-oxidizing atmosphere at a temperature of equal to or higher than 700° C. and equal to or less than 1000° C.

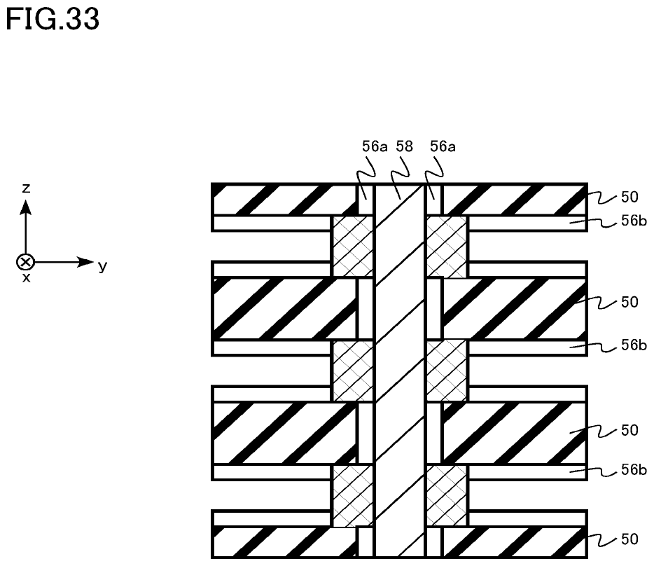

Next, the first titanium nitride film 60a is removed (FIG. 33). The first titanium nitride film 60a is removed by, for example, wet etching.

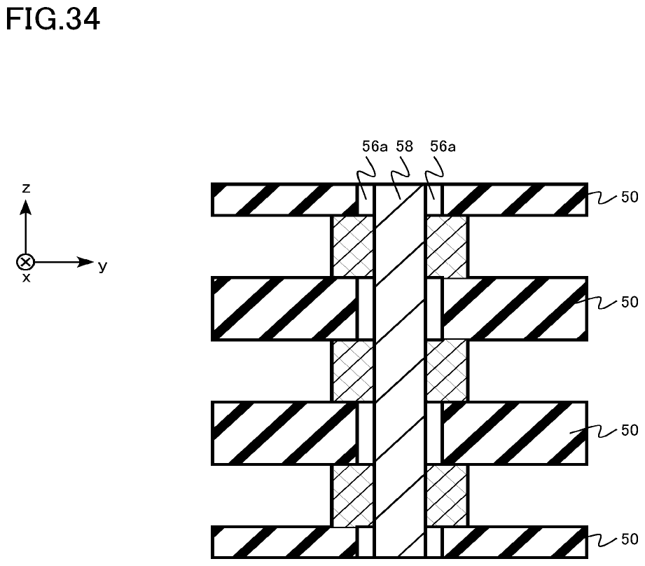

Next, a part of the second zirconium oxide film 56b remaining in the amorphous state is removed (FIG. 34). A part of the second zirconium oxide film 56b is removed by, for example, wet etching.

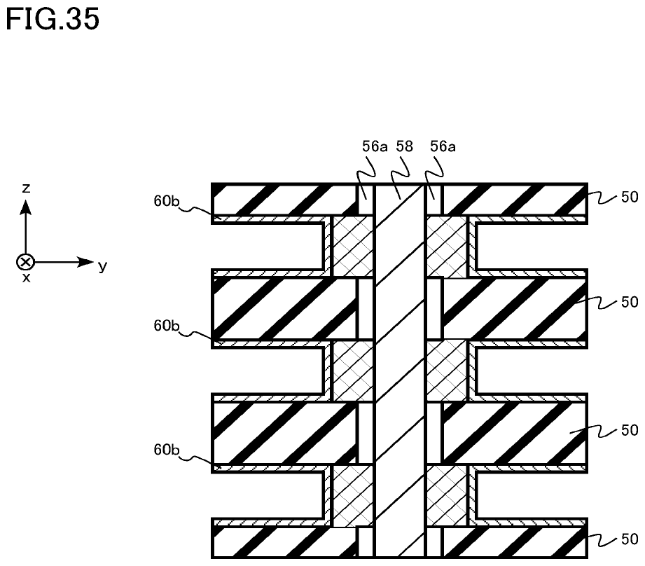

Next, a second titanium nitride film 60b is formed (FIG. 35). The second titanium nitride film 60b is formed, for example, by the CVD method.

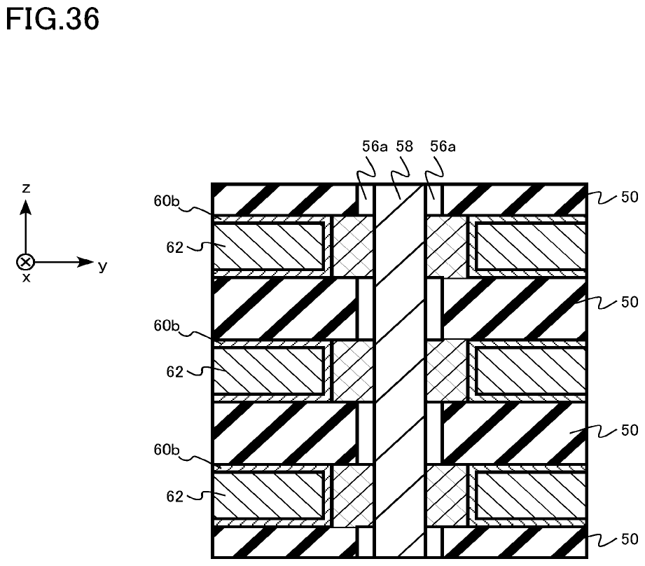

Next, a tungsten film 62 is formed on the second titanium nitride film 60b (FIG. 36). The tungsten film 62 is formed, for example, by the CVD method. The tungsten film 62 is an example of the main metal layer 12.

By the above-described manufacturing method, the memory cell array 300 of the memory device of the third embodiment is manufactured.

Next, the functions and effects of the memory device of the third embodiment will be described.

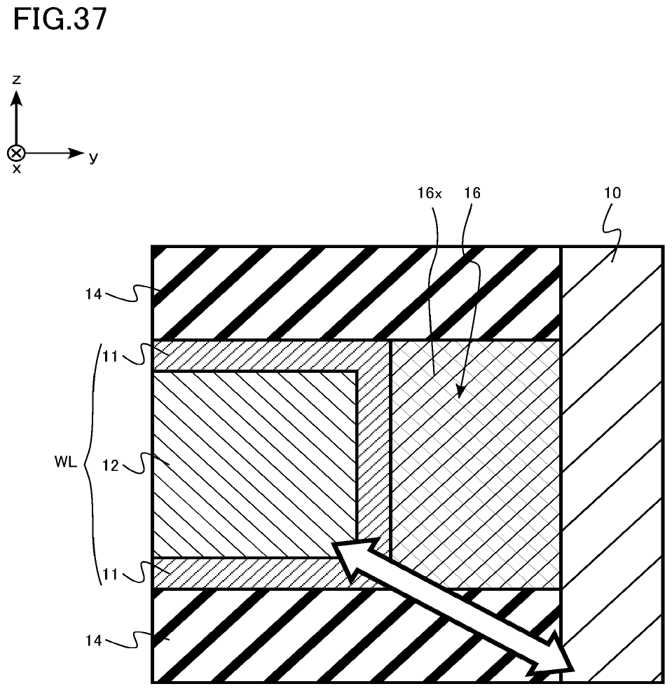

FIG. 37 is a schematic cross-sectional view of the memory cell of the memory device of the comparative example. FIG. 37 is an enlarged cross-sectional view of a part of the memory cell. FIG. 37 is a yz cross-sectional view of the memory cell. FIG. 37 is a view corresponding to FIG. 25 of the memory device of the third embodiment.

The memory cell of the comparative example is different from the memory cell of the third embodiment in that the intermediate insulating layer 17 is not provided between the semiconductor layer 10 and the interlayer insulating layer 14.

In the memory cell of the comparative example, the gate leakage current between the word line WL and the semiconductor layer 10 in the path via the interlayer insulating layer 14 (double-headed arrow in FIG. 37) possibly becomes a problem. When the gate leakage current increases, for example, the power consumption of the three-dimensional NAND flash memory increases, which becomes a problem. The gate leakage current is a tunnel current in which electrons tunnel through the barrier of the interlayer insulating layer 14 to flow.

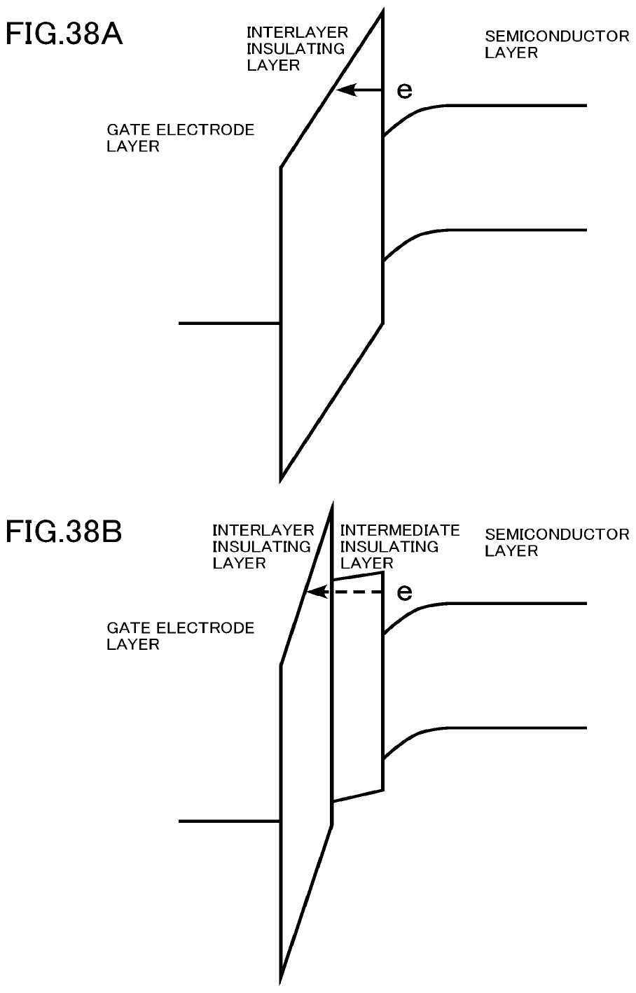

FIGS. 38A and 38B are explanatory views of the functions and effects of the memory device of the third embodiment. FIG. 38A is a band diagram of the memory cell of the comparative example, and FIG. 38B is a band diagram of the memory cell of the third embodiment.

The memory cell of the third embodiment includes the intermediate insulating layer 17 between the semiconductor layer 10 and the interlayer insulating layer 14. The interlayer insulating layer 14 of the memory cell of the comparative example and the interlayer insulating layer 14 of the memory cell of the third embodiment include the first insulator. The intermediate insulating layer 17 includes a second oxide. The dielectric constant of the second oxide is higher than the dielectric constant of the first insulator. Therefore, the dielectric constant of the intermediate insulating layer 17 is higher than the dielectric constant of the interlayer insulating layer 14.

The memory cell of the third embodiment includes an interlayer insulating layer 14 and an intermediate insulating layer 17 having a higher dielectric constant than that of the interlayer insulating layer 14 between the word line WL and the semiconductor layer 10. Thus, in the case of the memory cell of the third embodiment, as shown in FIGS. 38A and 38B, the tunnel distance (dotted arrow in FIG. 38B) when the electron tunnels from the semiconductor layer 10 to the word line WL becomes longer than the tunnel distance (solid arrow in FIG. 38A) in the case of the memory cell of the comparative example. Therefore, as compared with the memory cell of the comparative example, the memory cell of the third embodiment has a reduced gate leakage current between the gate electrode layer and the semiconductor layer 10.

The second oxide included in the intermediate insulating layer 17 is preferably paraelectric. The intermediate insulating layer 17 is preferably a paraelectric layer.

For example, if the intermediate insulating layer 17 is a ferroelectric layer, the polarization inversion of the intermediate insulating layer 17 possibly varies the threshold voltage of the memory cell transistor. By making the intermediate insulating layer 17 a paraelectric layer, it is possible to suppress variation in the threshold voltage of the memory cell transistor.

The thickness (t3 in FIG. 25) of the gate insulating layer 16 in the y-direction from the word line WL toward the semiconductor layer 10 is thicker than the thickness (t4 in FIG. 25) of the intermediate insulating layer 17 in the y-direction from the word line WL toward the semiconductor layer 10. In other words, the thickness of the intermediate insulating layer 17 is smaller than the thickness of the gate insulating layer 16. By making the thickness of the intermediate insulating layer 17 thinner than the thickness of the gate insulating layer 16, it is possible to suppress crystallization of the intermediate insulating layer 17 at the time of manufacturing the intermediate insulating layer 17. Therefore, it becomes easy to keep the intermediate insulating layer 17 in an amorphous state. Hence, it becomes easy to make the intermediate insulating layer 17 a paraelectric layer.

From the viewpoint of keeping the intermediate insulating layer 17 in an amorphous state and making it a paraelectric layer, the thickness t4 of the intermediate insulating layer 17 in the y-direction from the word line WL toward the semiconductor layer 10 is preferably equal to or less than 8 nm, and more preferably equal to or less than 5 nm.

From the viewpoint of keeping the intermediate insulating layer 17 in an amorphous state and making it a paraelectric layer, the thickness t3 of the gate insulating layer 16 in the y-direction from the word line WL toward the semiconductor layer 10 is preferably equal to or larger than 1.2 times, and more preferably equal to or larger than 1.5 times the thickness t4 of the intermediate insulating layer 17 in the y-direction from the word line WL toward the semiconductor layer 10.

If the intermediate insulating layer 17 is crystalline, that is, if the second oxide included in the intermediate insulating layer 17 is crystalline, it is preferable to include a crystal other than orthorhombic crystal. Since the second oxide includes a crystal other than orthorhombic crystal, the second oxide becomes paraelectric. Since the second oxide includes a crystal other than orthorhombic crystal, the intermediate insulating layer 17 becomes paraelectric layer.

From the viewpoint of making it easy to form the gate insulating layer 16 and the intermediate insulating layer 17, the first oxide included in the first ferroelectric region 16x and the second oxide included in the intermediate insulating layer 17 preferably have the identical chemical composition.

The first oxide is preferably zirconium oxide from the viewpoint of increasing the spontaneous polarization amount of the gate insulating layer 16.

The atomic ratio (Zr/(Hf+Zr)) of zirconium (Zr) contained in the first oxide to the total sum of hafnium (Hf) and zirconium (Zr) contained in the first oxide is preferably equal to or more than 50% and equal to or less 90%, and more preferably equal to or more than 65% and equal to or less than 75%. By exceeding the above-described lower limit value, the spontaneous polarization amount of the gate insulating layer 16 can be increased.

By lowering the atomic ratio (Zr/(Hf+Zr)), the dielectric constant of the first oxide is lowered, and it is possible to increase the EOT converted into the silicon oxide film of the gate insulating layer 16. The atomic ratio (Zr/(Hf+Zr)) is preferably equal to or less than 75% from the viewpoint of thickening the EOT of the gate insulating layer 16.

By raising the atomic ratio (Zr/(Hf+Zr)), the dielectric constant of the first oxide is raised, and it is possible to decrease the equivalent oxide thickness (EOT) converted into the silicon oxide film of the gate insulating layer 16. The atomic ratio (Zr/(Hf+Zr)) is preferably equal to or less than 65% from the viewpoint of thinning the EOT of the gate insulating layer 16.

If the first oxide is hafnium oxide, the first oxide preferably contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). Since hafnium oxide contains the above-mentioned additive element, ferroelectricity becomes likely to be expressed in the hafnium oxide.

(Variation)

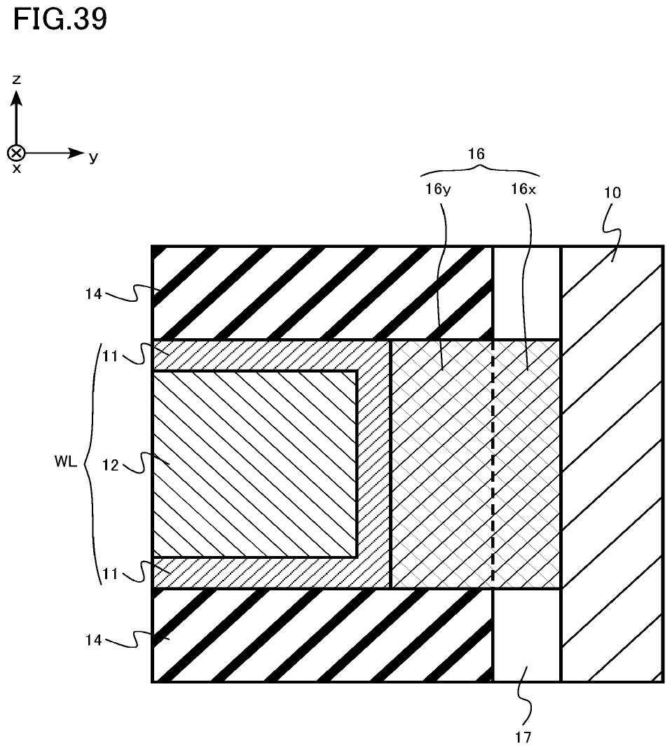

FIG. 39 is a schematic cross-sectional view of the memory cell of the memory device of the variation of the third embodiment. FIG. 39 is an enlarged cross-sectional view of a part of the memory cell. FIG. 39 is a yz cross-sectional view of the memory cell. FIG. 39 is a view corresponding to FIG. 25 of the memory device of the third embodiment.

The three-dimensional NAND flash memory of the variation of the third embodiment is different from the three-dimensional NAND flash memory of the third embodiment in that the gate insulating layer 16 includes a second ferroelectric region 16y disposed between the first ferroelectric region 16x and the word line WL, the second ferroelectric region 16y including a third oxide containing at least one of hafnium oxide or zirconium oxide and having a chemical composition different from that of the first oxide. The first ferroelectric region 16x is an example of the first region. The second ferroelectric region 16y is an example of the second region.

The second ferroelectric region 16y includes the third oxide containing at least one of orthorhombic hafnium oxide or orthorhombic zirconium oxide. The third oxide is ferroelectric. The third oxide is crystalline. The second ferroelectric region 16y is crystalline.

The chemical composition of the third oxide included in the second ferroelectric region 16y is different from the chemical composition of the first oxide included in the first ferroelectric region 16x.

The main crystal contained in the third oxide is an orthorhombic crystal. Among the crystals contained in the third oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, or triclinic crystal.

The third oxide is hafnium oxide mainly composed of orthorhombic hafnium oxide, for example. Among the crystals of hafnium oxide contained in the second oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The third oxide is hafnium oxide mainly composed of orthorhombic zirconium oxide, for example. Among the crystals of zirconium oxide contained in the third oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The third oxide may contain both hafnium (Hf) and zirconium (Zr). The atomic ratio (Zr/(Hf+Zr)) of zirconium (Zr) contained in the third oxide to the total sum of hafnium (Hf) and zirconium (Zr) contained in the second oxide is equal to or more than 50% and equal to or less than 90%.

The third oxide may contain both ferroelectric hafnium oxide and ferroelectric zirconium oxide. The third oxide may be a mixed crystal of, for example, ferroelectric hafnium oxide and ferroelectric zirconium oxide.

The third oxide contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr).

Since the third oxide contains the above-described additive element, if the third oxide is hafnium oxide, it becomes possible to increase the proportion of the orthorhombic crystal in the hafnium oxide contained in the second ferroelectric region 16y. Since the second oxide contains the above-described additive element, if the second oxide is hafnium oxide, ferroelectricity becomes likely to be expressed in the hafnium oxide contained in the second ferroelectric region 16y.

The second ferroelectric region 16y is composed mainly of the third oxide. Being composed mainly of the third oxide means that the mole fraction of the third oxide is the highest among the substances contained in the second ferroelectric region 16y. The mole fraction of the second oxide is, for example, equal to or more than 90% and equal to or less than 100%.

The three-dimensional NAND flash memory of the variation of the third embodiment can be manufactured by changing the chemical composition of the first zirconium oxide film 56a and the chemical composition of the second zirconium oxide film 56b in the manufacturing method of the three-dimensional NAND flash memory of the third embodiment, for example.

Thus, according to the third embodiment and its variation, it is possible to achieve a memory device capable of reducing the gate leak current.

### Fourth Embodiment

The memory device of the fourth embodiment is different from the memory device of the first embodiment in that the gate insulating layer includes a second region disposed between the first region and the first gate electrode layer and including a first insulator having a chemical composition different from that of the first oxide. The memory device of the fourth embodiment is different from the memory device of the first embodiment in that the first insulating layer includes a second insulator, the memory device further includes an intermediate insulating layer provided between the semiconductor layer and the first insulating layer, the intermediate insulating layer including a second oxide including at least one of hafnium oxide or zirconium oxide, the second oxide having a dielectric constant higher than a dielectric constant of the second insulator, and a thickness of the gate insulating layer in a second direction from the first gate electrode layer toward the semiconductor layer is thicker than a thickness of the intermediate insulating layer in the second direction. The memory device of the fourth embodiment includes a form in which the configurations of the memory devices of the second embodiment and the third embodiment are added to the memory device of the first embodiment. Hereinafter, part of description of the contents overlapping the first to third embodiments will be omitted.

The memory device of the fourth embodiment is a three-dimensional NAND flash memory having a memory cell transistor MT. The memory cell transistor MT includes ferroelectric in a gate insulating layer. The memory device of the first embodiment is a 3-terminal type ferroelectric memory.

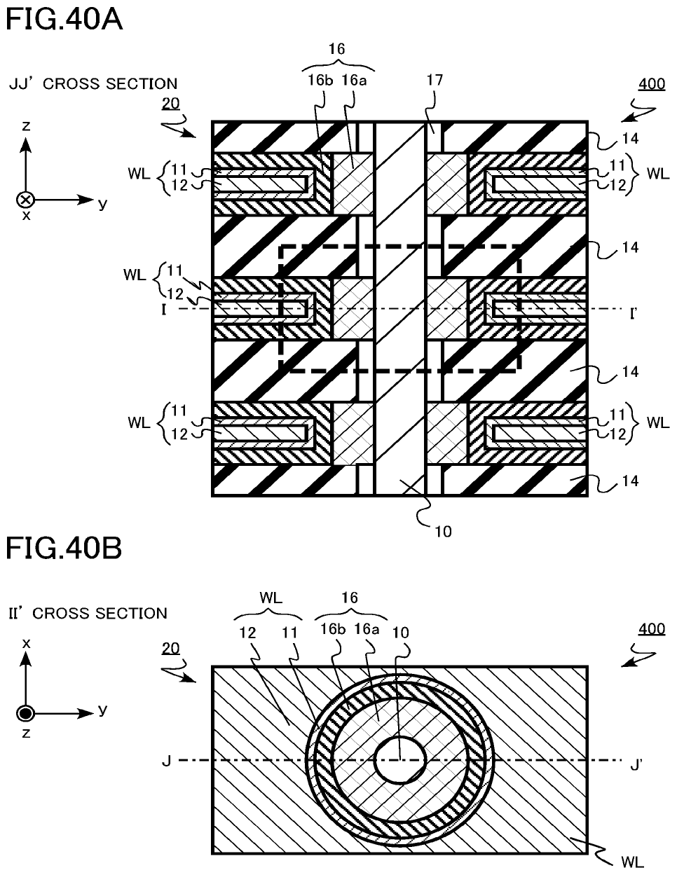

FIGS. 40A and 40B are schematic cross-sectional views of a part of the memory cell array of the memory device of the fourth embodiment. FIGS. 40A and 40B show a cross section of a plurality of memory cells in a memory cell array 400.

FIG. 40A is a yz cross-sectional view of the memory cell array 400. FIG. 40A is a JJ′ cross section of FIG. 40B. FIG. 40B is an xy cross-sectional view of the memory cell array 400. FIG. 40B is an II′ cross section of FIG. 40A. In FIG. 40A, a region enclosed by a broken line is one memory cell.

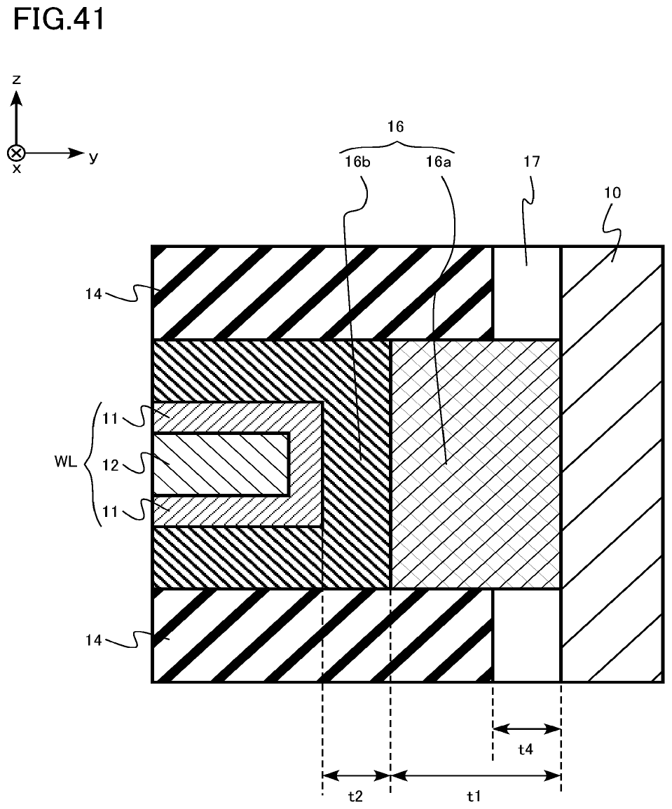

FIG. 41 is a schematic cross-sectional view of the memory cell of the memory device of the fourth embodiment. FIG. 41 is an enlarged cross-sectional view of a part of the memory cell. FIG. 41 is a yz cross-sectional view of the memory cell.

Hereinafter, the x-direction, y-direction, and z-direction shown in FIGS. 40A, 40B, and 41 are defined as the third direction, the second direction, and the first direction, respectively. In the present description, the x-direction, y-direction, and z-direction shall include not only the orientations of the arrows in FIGS. 40A, 40B, and 41 but also the orientations opposite to the arrow directions.

As shown in FIGS. 40A and 40B, the memory cell array 400 includes the plurality of word lines WL, a semiconductor layer 10, a plurality of interlayer insulating layers 14, a gate insulating layer 16, and an intermediate insulating layer 17. The plurality of word lines WL and the plurality of interlayer insulating layers 14 constitute a stacked body 20.

The word line WL is an example of the gate electrode layer. The interlayer insulating layer 14 is an example of the insulating layer. Of the plurality of word lines WL, the word line WL disposed at the center in FIG. 40A is an example of the first gate electrode layer. Of the plurality of word lines WL, the word line WL disposed at the top in FIG. 40A is an example of the second gate electrode layer. In FIG. 40A, the interlayer insulating layer 14 disposed between the word line WL disposed at the center and the word line WL disposed at the top is an example of the first insulating layer.

The second gate electrode layer is adjacent to the first gate electrode layer in the z-direction. The first insulating layer is disposed between the first gate electrode layer and the second gate electrode layer.

The word line WL has, for example, a barrier metal layer 11 and a main metal layer 12. The gate insulating layer 16 has a ferroelectric region 16a and a paraelectric region 16b. The ferroelectric region 16a is an example of the first region. The paraelectric region 16b is an example of the second region.

The word line WL and the interlayer insulating layer 14 are provided on a semiconductor substrate not illustrated, for example. The semiconductor substrate is, for example, a silicon substrate.

The word lines WL and the interlayer insulating layers 14 are alternately stacked on the semiconductor substrate in the z-direction. The word lines WL are disposed to be spaced apart in the z-direction. The plurality of word lines WL and the plurality of interlayer insulating layers 14 constitute a stacked body 20.

The word line WL is, for example, a plate-like conductor. The word line WL includes, for example, a metal, a metal nitride, a metal carbide, or a semiconductor. The word line WL has, for example, a barrier metal layer 11 and a main metal layer 12.

The barrier metal layer 11 is, for example, a metal nitride or a metal carbide. The barrier metal layer 11 is, for example, titanium nitride, tantalum nitride, tungsten nitride, titanium carbide, tungsten carbide, or tantalum carbide. The main metal layer 12 is, for example, a metal. The main metal layer 12 is, for example, tungsten (W), titanium (Ti), or tantalum (Ta).

The word line WL functions as a control electrode of the memory cell transistor MT. The word line WL is an example of the gate electrode layer.

The thickness of the word line WL in the z-direction is, for example, equal to or more than 5 nm and equal to or less than 40 nm.

The interlayer insulating layer 14 separates the word lines WLs. The interlayer insulating layer 14 includes the second insulator. The second insulator is, for example, an oxide, an oxynitride, or a nitride. The second insulator is, for example, silicon oxide.

The interlayer insulating layer 14 is composed mainly of the second insulator. Being composed mainly of the second insulator means that the mole fraction of the second insulator is the highest among the substances contained in the interlayer insulating layer 14. The mole fraction of the second insulator is, for example, equal to or more than 90% and equal to or less than 100%. The interlayer insulating layer 14 is, for example, silicon oxide.

The thickness of the interlayer insulating layer 14 in the z-direction is, for example, equal to or more than 5 nm and equal to or less than 40 nm.

The semiconductor layer 10 is provided in the stacked body 20. The semiconductor layer 10 extends in the z-direction. The semiconductor layer 10 is provided to penetrate the stacked body 20. The semiconductor layer 10 is, for example, cylindrical.

The semiconductor layer 10 is, for example, a polycrystalline semiconductor. The semiconductor layer 10 is, for example, polycrystalline silicon. The semiconductor layer 10 functions as a channel of the memory cell transistor MT.

The gate insulating layer 16 is provided between the semiconductor layer 10 and the word line WL. The gate insulating layer 16 is divided between adjacent memory cell transistors MT.

The gate insulating layer 16 comes into contact with, for example, the semiconductor layer 10 and the word line WL. The gate insulating layer 16 includes the ferroelectric region 16a and the paraelectric region 16b.

The ferroelectric region 16a includes the first oxide containing at least one of an orthorhombic hafnium oxide or an orthorhombic zirconium oxide. The first oxide is ferroelectric. The first oxide is crystalline. The ferroelectric region 16a is crystalline.

The main crystal contained in the first oxide is an orthorhombic crystal. Among the crystals contained in the first oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, or triclinic crystal.

The first oxide is hafnium oxide mainly composed of orthorhombic hafnium oxide, for example. Among the crystals of hafnium oxide contained in the first oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The first oxide is zirconium oxide mainly composed of orthorhombic zirconium oxide, for example. Among the crystals of zirconium oxide contained in the first oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The first oxide may contain both hafnium (Hf) and zirconium (Zr). The atomic ratio (Zr/(Hf+Zr)) of zirconium (Zr) contained in the first oxide to the total sum of hafnium (Hf) and zirconium (Zr) contained in the first oxide is equal to or more than 50% and equal to or less than 90%.

The first oxide may contain both ferroelectric hafnium oxide and ferroelectric zirconium oxide. The first oxide may be a mixed crystal of, for example, ferroelectric hafnium oxide and ferroelectric zirconium oxide.

The first oxide contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). The additive element is an example of the second element. Since the first oxide contains the above-described additive element, if the first oxide is hafnium oxide, it becomes possible to increase the proportion of the orthorhombic crystal in the hafnium oxide contained in the ferroelectric region 16a. Since the first oxide contains the above-described additive element, if the first oxide is hafnium oxide, ferroelectricity becomes likely to be expressed in the hafnium oxide contained in the ferroelectric region 16a.

The ferroelectric region 16a is composed mainly of the first oxide. Being composed mainly of the first oxide means that the mole fraction of the first oxide is the highest among the substances contained in the ferroelectric region 16a. The mole fraction of the first oxide is, for example, equal to or more than 90% and equal to or less than 100%.

The thickness (t1 in FIG. 41) of the ferroelectric region 16a in the y-direction from the word line WL toward the semiconductor layer 10 is, for example, equal to or more than 3 nm and equal to or less than 15 nm.

The paraelectric region 16b is disposed between the ferroelectric region 16a and the word line WL. The paraelectric region 16b includes a first insulator having a chemical composition different from that of the first oxide.

The first insulator is paraelectric. The first insulator is amorphous or crystalline. The paraelectric region 16b is amorphous or crystalline.

If the first insulator is crystalline, the main crystal contained in the first insulator is, for example, a crystal other than orthorhombic crystal. The crystals other than the orthorhombic crystal are cubic crystal, hexagonal crystal, tetragonal crystal, monoclinic crystal, and triclinic crystal.

The first insulator is an oxide, a nitride, or an oxynitride. The first insulator is, for example, silicon oxide, aluminum oxide, yttrium oxide, or titanium oxide. The first insulator is, for example, aluminum oxide or zirconium oxide other than orthorhombic crystal. The first insulator is hafnium oxide containing at least any one element selected from the group consisting of, for example, silicon (Si), aluminum (Al), yttrium (Y), zirconium (Zr), and lanthanum (La).

The first insulator is, for example, silicon nitride or aluminum nitride. The first insulator is, for example, silicon oxynitride.

The paraelectric region 16b is composed mainly of the first insulator. Being composed mainly of the first insulator means that the mole fraction of the first insulator is the highest among the substances contained in the paraelectric region 16b. The mole fraction of the first insulator is, for example, equal to or more than 90% and equal to or less than 100%.

The thickness (t2 in FIG. 41) of the paraelectric region 16b in the y-direction from the word line WL toward the semiconductor layer 10 is thinner than the thickness (t1 in FIG. 41) of the ferroelectric region 16a in the y-direction from the word line WL toward the semiconductor layer 10. The thickness t2 of the paraelectric region 16b in the y-direction is, for example, equal to or more than 0.5 nm and equal to or less than 15 nm.

The intermediate insulating layer 17 is provided between the semiconductor layer 10 and the interlayer insulating layer 14. The intermediate insulating layer 17 includes a second oxide containing at least one of hafnium oxide or zirconium oxide. The second oxide is, for example, paraelectric. The second oxide is amorphous or crystalline. The intermediate insulating layer 17 is, for example, amorphous or crystalline.

For example, if the second oxide is crystalline, the second oxide contains a crystal other than orthorhombic crystal. If the second oxide is crystalline, the main crystal contained in the second oxide is, for example, a crystal other than orthorhombic crystal. The crystals other than the orthorhombic crystal are cubic crystal, hexagonal crystal, tetragonal crystal, monoclinic crystal, or triclinic crystal.

The dielectric constant of the second oxide is higher than the dielectric constant of the second insulator included in the interlayer insulating layer 14.

For example, the first oxide included in the ferroelectric region 16a and the second oxide included in the intermediate insulating layer 17 have the identical chemical composition.

The intermediate insulating layer 17 is composed mainly of the second oxide. Being composed mainly of the second oxide means that the mole fraction of the second oxide is the highest among the substances contained in the intermediate insulating layer 17. The mole fraction of the second oxide is, for example, equal to or more than 90%.

The thickness (t1 in FIG. 41) of the ferroelectric region 16a in the y-direction from the word line WL toward the semiconductor layer 10 is thicker than the thickness (t4 in FIG. 41) of the intermediate insulating layer 17 in the y-direction from the word line WL toward the semiconductor layer 10. The thickness (t1 in FIG. 41) of the ferroelectric region 16a in the y-direction from the word line WL toward the semiconductor layer 10 is equal to or larger than 1.2 times and equal to or smaller than 5 times the thickness (t4 in FIG. 41) of the intermediate insulating layer 17 in the y-direction from the word line WL toward the semiconductor layer 10. The thickness (t4 in FIG. 41) of the intermediate insulating layer 17 in the y-direction is, for example, equal to or more than 0.5 nm and equal to or less than 15 nm.

In the memory cell of the fourth embodiment, the polarization inversion state of the ferroelectric included in the ferroelectric region 16a of the gate insulating layer 16 is controlled by a voltage applied between the word line WL and the semiconductor layer 10. The threshold voltage of the memory cell transistor MT changes depending on the polarization inversion state of the ferroelectric region 16a.

When the threshold voltage of the memory cell transistor MT changes, the on-current of the memory cell transistor MT changes. For example, if a state where the threshold voltage is high and the on-current is low is defined as data “0”, and a state where the threshold voltage is low and the on-current is high is defined as data “1”, the memory cell can store 1-bit data of “0” and “1”.

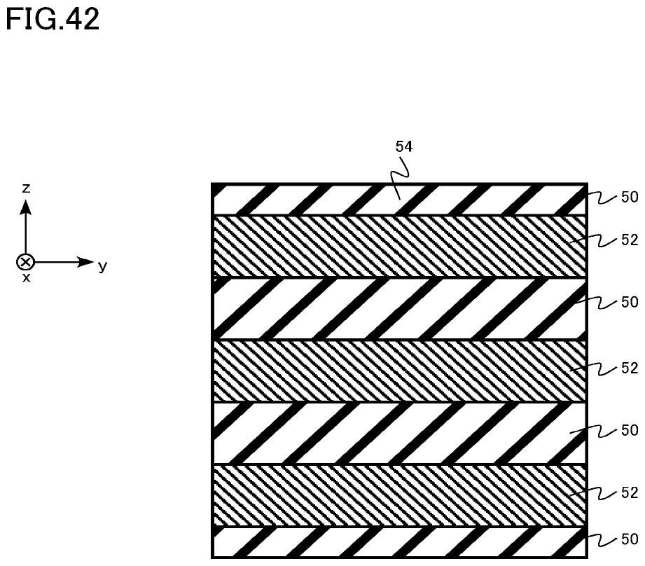

Next, an example of the manufacturing method of the memory device according to the fourth embodiment will be described. FIGS. 42, 43, 44, 45, 46, 47, 48, 49, 50, 51, 52, 53, and 54 are schematic cross-sectional views showing the manufacturing method of the memory device of the fourth embodiment. FIGS. 42, 43, 44, 45, 46, 47, 48, 49, 50, 51, 52, 53, and 54 each show a cross section corresponding to FIG. 40A. FIGS. 42, 43, 44, 45, 46, 47, 48, 49, 50, 51, 52, 53, and 54 show an example of a manufacturing method of the memory cell array 400 of the memory device.

First, a silicon oxide layer 50 and a silicon nitride layer 52 are alternately stacked on a semiconductor substrate not illustrated (FIG. 42). The silicon oxide layer 50 and the silicon nitride layer 52 form the stacked body 20. The silicon oxide layer 50 and the silicon nitride layer 52 are formed, for example, by the CVD method. A part of the silicon oxide layer 50 eventually becomes the interlayer insulating layer 14.

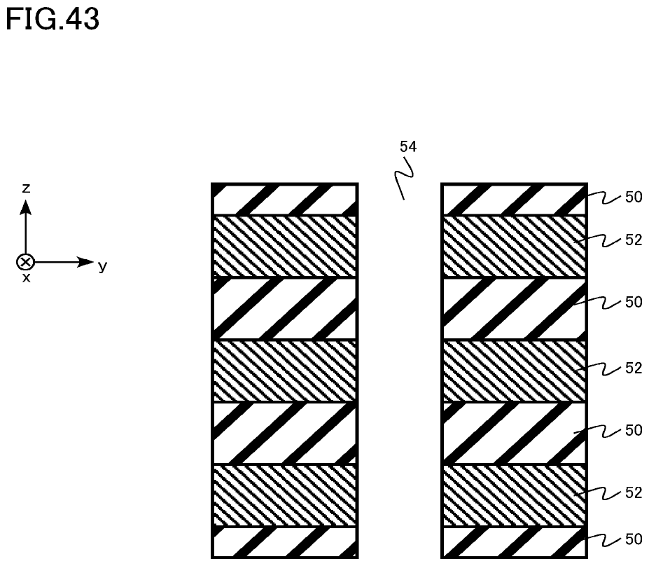

Next, an opening 54 is formed in the silicon oxide layer 50 and the silicon nitride layer 52 (FIG. 43). The opening 54 is formed by, for example, the lithography method and the RIE method.

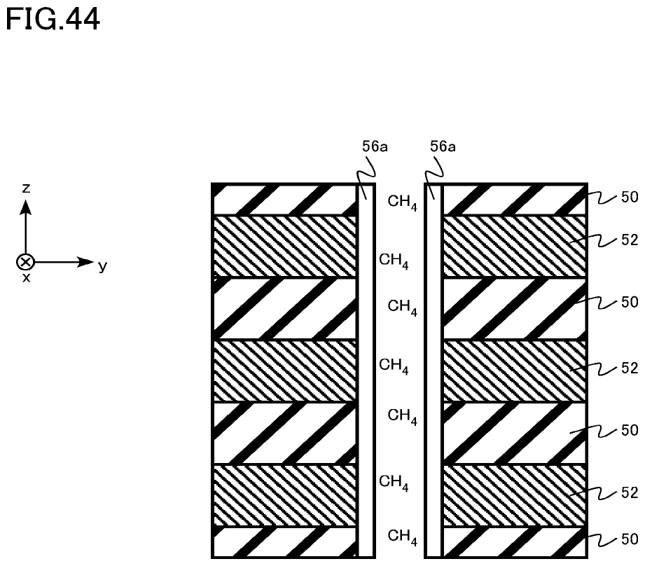

Next, on the inner surface of the opening 54, a first zirconium oxide film 56a is formed (FIG. 44). The first zirconium oxide film 56a contains, for example, hafnium (Hf). The first zirconium oxide film 56a is formed by, for example, the ALD method. The first zirconium oxide film 56a is amorphous. The first zirconium oxide film 56a eventually becomes a part of the gate insulating layer 16 and the intermediate insulating layer 17.

The film forming temperature of the first zirconium oxide film 56a is, for example, equal to or higher than 150° C. and equal to or lower than 350° C. The film thickness of the first zirconium oxide film 56a is, for example, equal to or less than 8 nm.

Next, heat treatment is performed in an atmosphere containing methane gas (CH₄). When heat treatment is performed in an atmosphere containing methane gas (CH₄), carbon (C) is contained as an impurity in the first zirconium oxide film 56a.

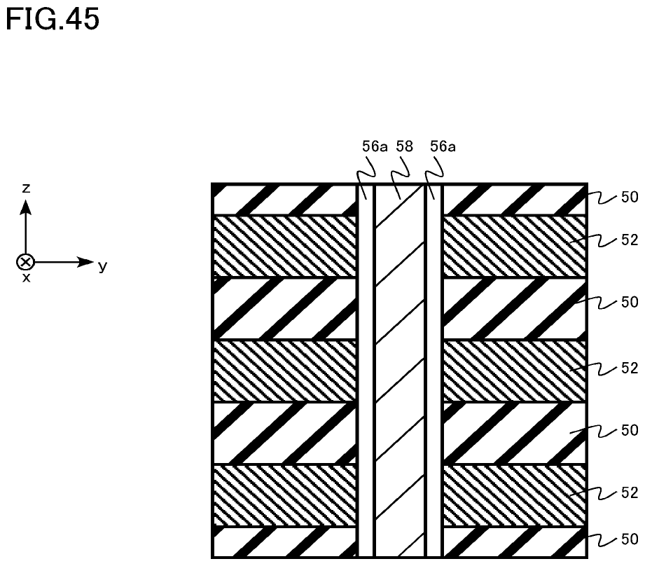

Next, an amorphous silicon film 58 is formed in the opening 54, and the opening 54 is embedded (FIG. 45). The amorphous silicon film 58 eventually becomes the semiconductor layer 10.

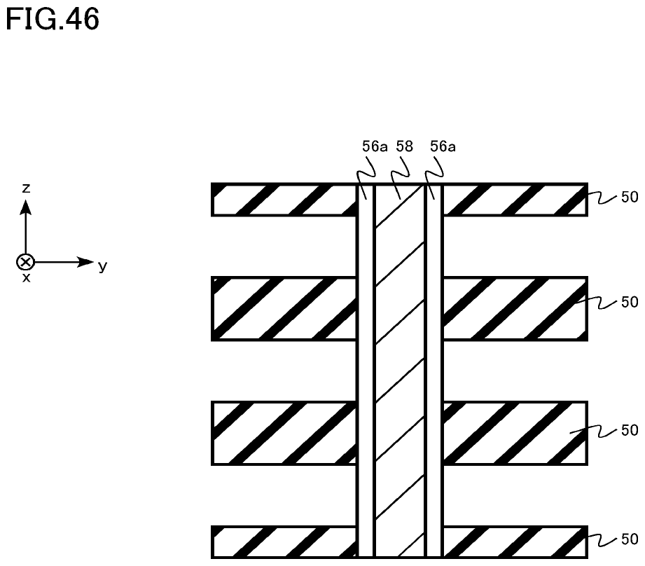

Next, the silicon nitride layer 52 is selectively removed by wet etching using an etching groove not illustrated (FIG. 46). For wet etching, for example, by using a phosphoric acid solution, the silicon nitride layer 52 is selectively etched with respect to the silicon oxide layer 50.

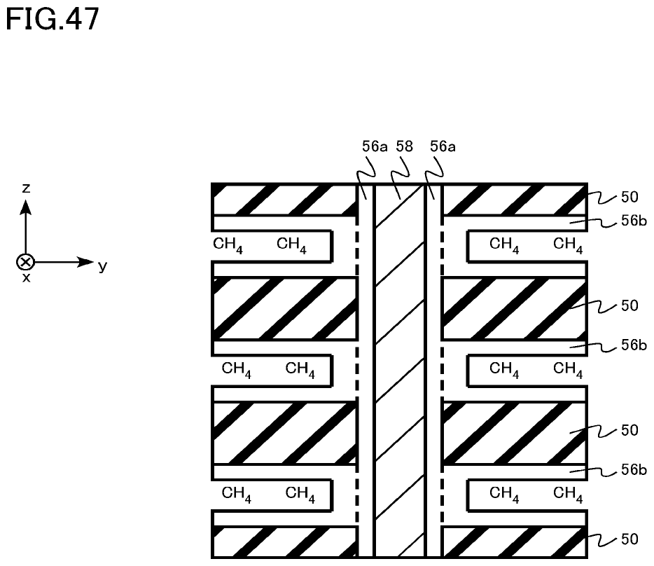

Next, a second zirconium oxide film 56b is formed (FIG. 47). The second zirconium oxide film 56b contains, for example, hafnium (Hf). The second zirconium oxide film 56b is formed by, for example, the ALD method. The second zirconium oxide film 56b is amorphous. A part of the second zirconium oxide film 56b eventually becomes a part of the ferroelectric region 16a of the gate insulating layer 16.

The film forming temperature of the second zirconium oxide film 56b is, for example, equal to or higher than 150° C. and equal to or lower than 350° C. The film thickness of the second zirconium oxide film 56b is, for example, equal to or greater than 2 nm.

Next, heat treatment is performed in an atmosphere containing methane gas (CH₄). When heat treatment is performed in an atmosphere containing methane gas (CH₄), carbon (C) is contained as an impurity in the second zirconium oxide film 56b.

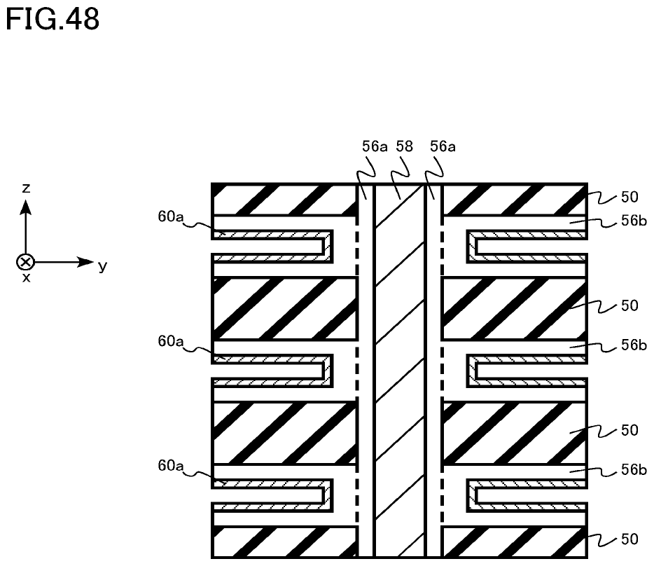

Next, a first titanium nitride film 60a is formed (FIG. 48). The first titanium nitride film 60a is formed, for example, by the CVD method.

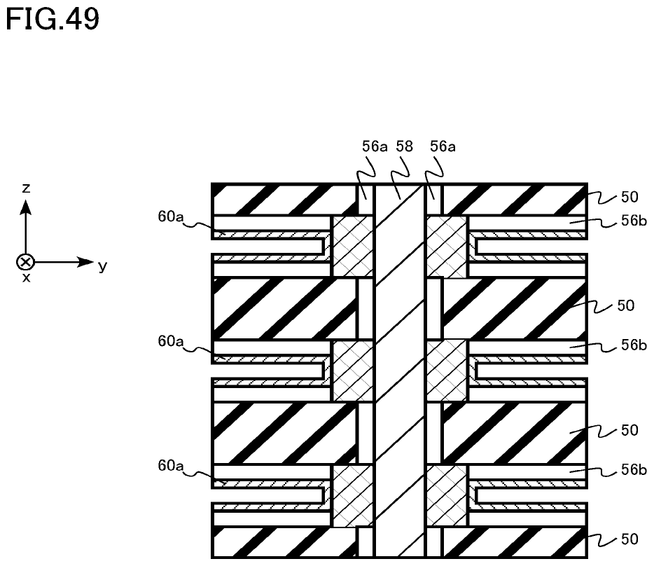

Next, crystallization annealing is performed to crystallize a part of the first zirconium oxide film 56a of amorphous and the second zirconium oxide film 56b of amorphous (FIG. 49). By crystallization annealing, the first zirconium oxide film 56a held between the first titanium nitride film 60a and the semiconductor layer 10 is crystallized into ferroelectric. By crystallization annealing, the second zirconium oxide film 56b held between the first titanium nitride film 60a and the semiconductor layer 10 is crystallized into ferroelectric. By crystallization annealing, an orthorhombic zirconium oxide is formed in a part of the first zirconium oxide film 56a and the second zirconium oxide film 56b.

In crystallization annealing, the first zirconium oxide film 56a between the interlayer insulating layer 14 and the semiconductor layer 10 is thin in film thickness, and hence crystallization does not proceed and the first zirconium oxide film 56a remains in an amorphous state. The first zirconium oxide film 56a between the interlayer insulating layer 14 and the semiconductor layer 10 eventually becomes the intermediate insulating layer 17.

In crystallization annealing, the second zirconium oxide film 56b between the first titanium nitride film 60a and the interlayer insulating layer 14 is thin in film thickness, and hence crystallization does not proceed and the second zirconium oxide film 56b remains in an amorphous state.

The crystallization annealing is performed, for example, in a non-oxidizing atmosphere at a temperature of equal to or higher than 700° C. and equal to or less than 1000° C.

Due to the crystallization annealing, the amorphous silicon film 58 is also crystallized to become a polycrystalline silicon film.

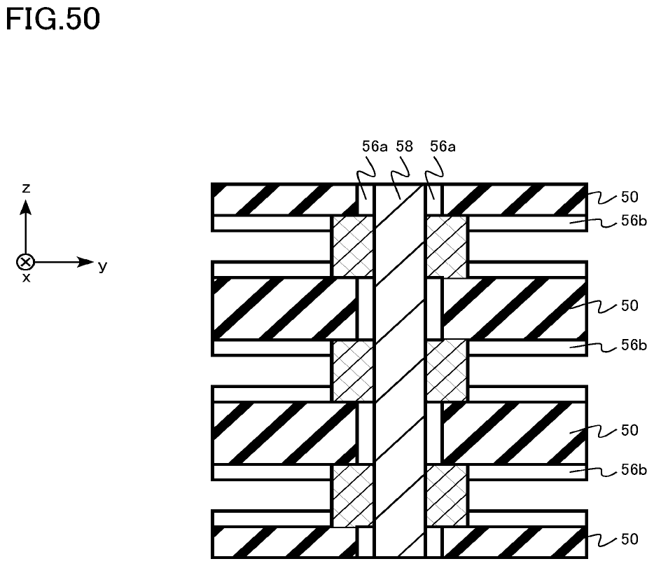

Next, the first titanium nitride film 60a is removed (FIG. 50). The first titanium nitride film 60a is removed by, for example, wet etching.

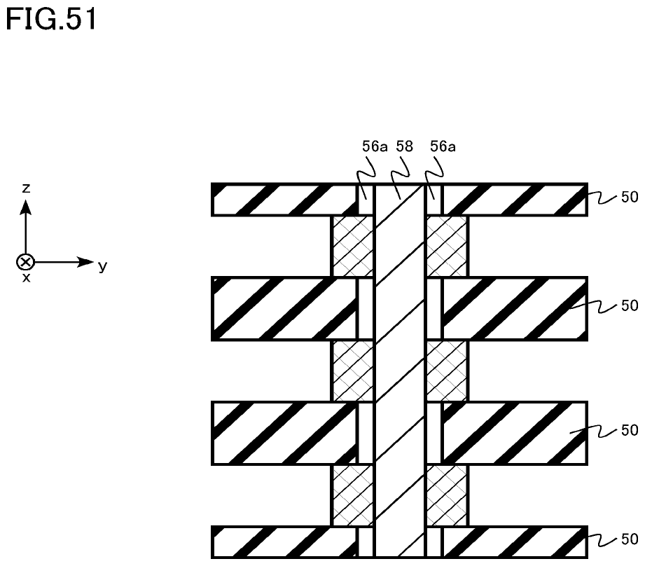

Next, a part of the second zirconium oxide film 56b remaining in the amorphous state is removed (FIG. 51). The second zirconium oxide film 56b is removed by, for example, wet etching.

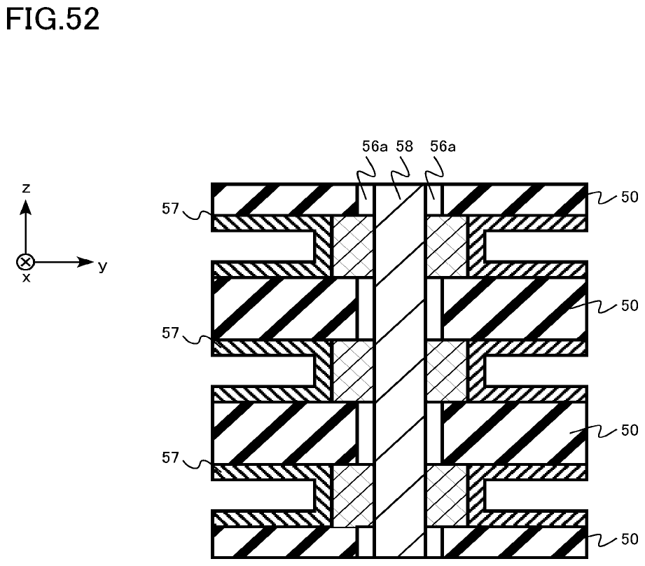

Next, a hafnium oxide film 57 is formed (FIG. 52). The hafnium oxide film 57 contains, for example, aluminum (Al). The atomic ratio (Al/(Hf+Al)) of aluminum (Al) contained in the hafnium oxide film 57 to the total sum of hafnium (Hf) and aluminum (Al) contained in the hafnium oxide film 57 is, for example, equal to or more than 5%.

The hafnium oxide film 57 is formed by, for example, the ALD method. The hafnium oxide film 57 is amorphous. The hafnium oxide film 57 eventually becomes the paraelectric region 16b of the gate insulating layer 16.

Since the hafnium oxide film 57 is amorphous, it becomes paraelectric. Since the hafnium oxide film 57 contains equal to or more than 5% of aluminum (Al) even if crystallized, the hafnium oxide film 57 does not become ferroelectric but becomes paraelectric.

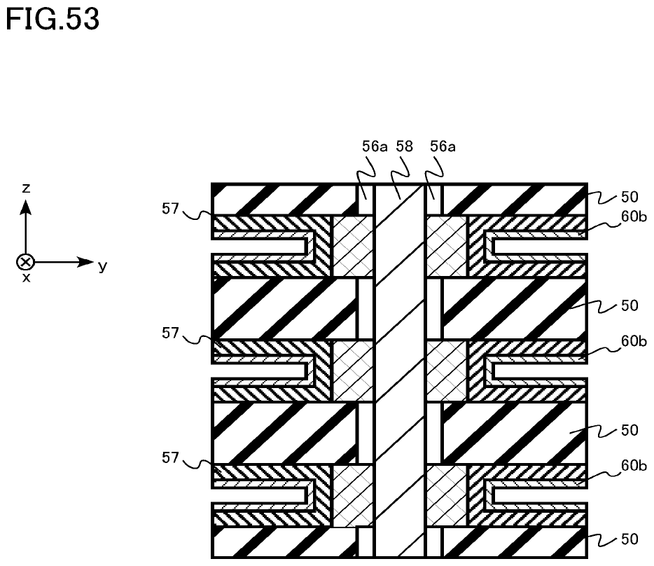

Next, a second titanium nitride film 60b is formed (FIG. 53). The second titanium nitride film 60b is formed, for example, by the CVD method.

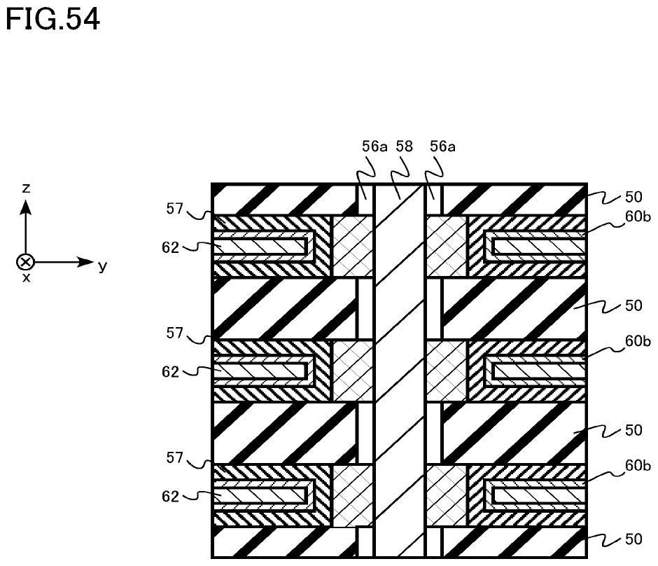

Next, a tungsten film 62 is formed on the second titanium nitride film 60b (FIG. 54). The tungsten film 62 is formed, for example, by the CVD method. The tungsten film 62 is an example of the main metal layer 12.

By the above-described manufacturing method, the memory cell array 400 of the memory device of the fourth embodiment is manufactured.

Thus, according to the fourth embodiment, since the gate insulating layer includes the first oxide containing an impurity element, a memory device having a large memory window can be achieved. According to the fourth embodiment, since the gate insulating layer includes the paraelectric region between the ferroelectric region and the gate electrode layer, a memory device having a large memory window can be achieved. According to the fourth embodiment, by providing the intermediate insulating layer, it is possible to achieve a memory device capable of reducing the gate leak current.

### Fifth Embodiment

The memory device according to a fifth embodiment includes a first conductive layer extending in a first direction, a second conductive layer extending in the first direction, a third conductive layer extending in a second direction intersecting the first direction, a first insulating film provided between the first conductive layer and the third conductive layer, the first insulating film including a first oxide containing at least one of hafnium oxide or zirconium oxide, the first insulating film including an orthorhombic crystal, and the first insulating film including at least one first element selected from the group consisting of carbon (C), nitrogen (N), chlorine (Cl), boron (B), hydrogen (H), fluorine (F), helium (He), and argon (Ar), and a second insulating film provided between the first insulating film and the third conductive layer, the second insulating film including a first insulator having a chemical composition different from a chemical composition of the first oxide. The memory device of the fifth embodiment is different from the memory device of the first embodiment in that the memory device of the fifth embodiment is a two-terminal type memory. Part of description of the contents overlapping the first embodiment will be omitted.

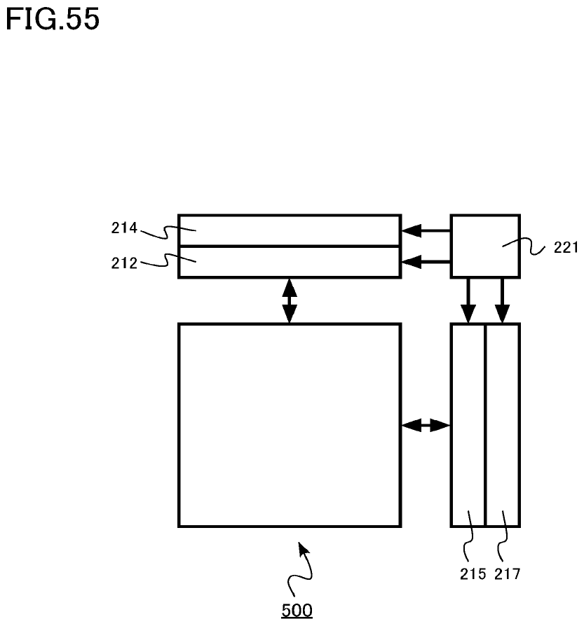

FIG. 55 is a block diagram of the memory device of the fifth embodiment. The memory device of the fifth embodiment is an FTJ memory.

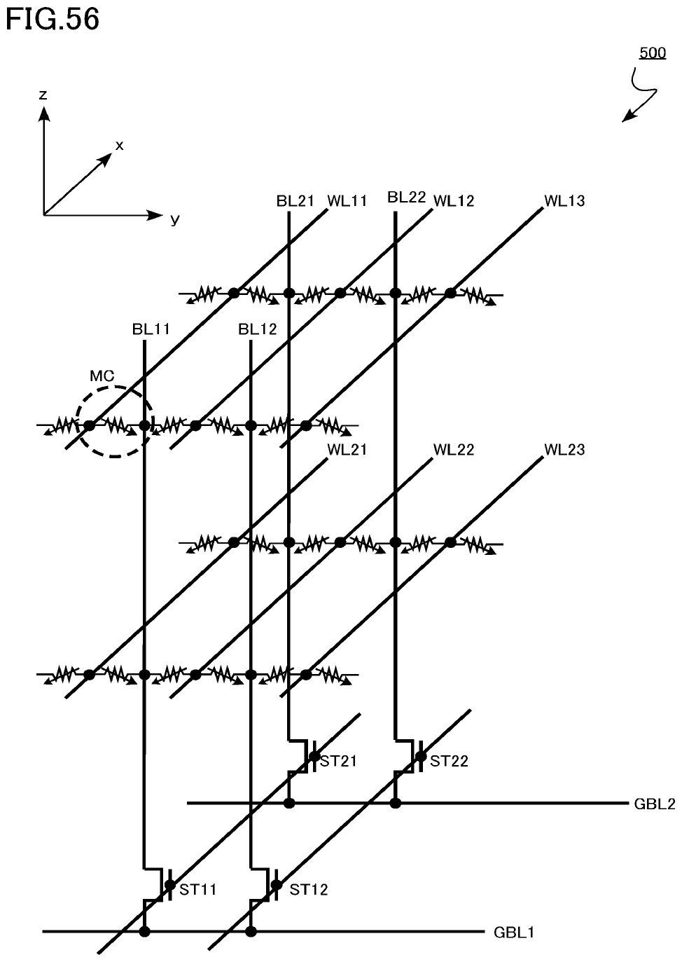

FIG. 56 is an equivalent circuit diagram of the memory cell array of the memory device of the fifth embodiment. FIG. 56 schematically shows the wiring structure in the memory cell array. A memory cell array 500 of the fifth embodiment includes a three-dimensional structure in which memory cells are three-dimensionally disposed.

As shown in FIG. 55, the memory device of the fifth embodiment includes the memory cell array 500, a word line driver circuit 212, a row decoder circuit 214, a sense amplifier circuit 215, a column decoder circuit 217, and a control circuit 221.

As shown in FIG. 56, a plurality of memory cells are three-dimensionally disposed in the memory cell array 500. In FIG. 56, a region enclosed by a dotted line corresponds to one memory cell MC.

The memory cell array 500 includes, for example, a plurality of word lines WL (WL11, WL12, WL13, WL21, WL22, and WL23) and a plurality of bit lines BL (BL11, BL12, BL21, and BL22). The word line WL extends in the x-direction. The bit line BL extends in the z-direction. The word line WL and the bit line BL intersect perpendicularly. The memory cell MC is disposed at the intersection of the word line WL and the bit line BL.

The plurality of word lines WL are electrically connected to the row decoder circuit 214. The plurality of bit lines BL are connected to the sense amplifier circuit 215. Selection transistors ST (ST11, ST21, ST12, and ST22) and global bit lines GBL (GBL1 and GBL2) are provided between the plurality of bit lines BL and the sense amplifier circuit 215.

The row decoder circuit 214 includes a function of selecting the word line WL in accordance with a row address signal having been input. The word line driver circuit 212 includes a function of applying a predetermined voltage to the word line WL selected by the row decoder circuit 214.

The column decoder circuit 217 includes a function of selecting the bit line BL in accordance with a column address signal having been input. The sense amplifier circuit 215 includes a function of applying a predetermined voltage to the bit line BL selected by the column decoder circuit 217. The sense amplifier circuit 215 includes a function of detecting and amplifying a current flowing through between the selected word line WL and the selected bit line BL.

The control circuit 221 includes a function of controlling the word line driver circuit 212, the row decoder circuit 214, the sense amplifier circuit 215, the column decoder circuit 217, and other circuits not illustrated.

The circuits such as the word line driver circuit 212, the row decoder circuit 214, the sense amplifier circuit 215, the column decoder circuit 217, and the control circuit 221 are configured by, for example, transistors and wiring layers using semiconductor layers not illustrated.

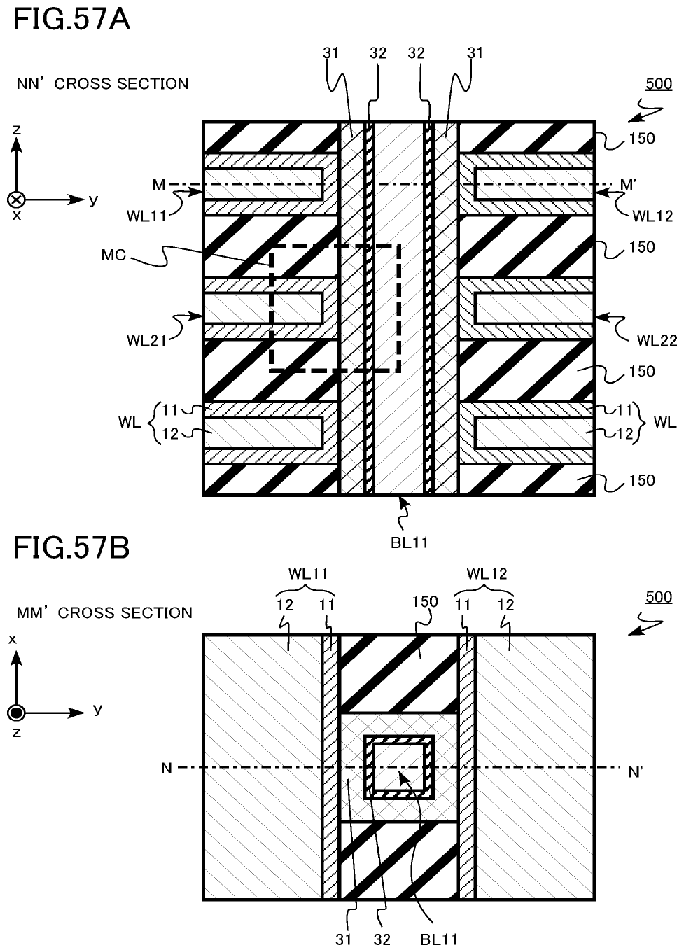

FIGS. 57A and 57B are schematic cross-sectional views of a part of the memory cell array of the memory device of the fifth embodiment. FIG. 57A is a yz cross-sectional view of the memory cell array 500. FIG. 57B is an xy cross-sectional view of the memory cell array 500. FIG. 57A is an NN′ cross section of FIG. 57B, and FIG. 57B is an MM′ cross section of FIG. 57A. In FIG. 57A, a region enclosed by a broken line is the one memory cell MC.

The memory cell array 500 includes the plurality of word lines including the word line WL11 and the word line WL21, the plurality of bit lines including the bit line BL11 and the bit line BL21, a first insulating film 31, a second insulating film 32, and an interlayer insulating layer 150. Hereinafter, a plurality of word lines including the word line WL11 and the word line WL12 are sometimes collectively referred to as simply the word line WL. A plurality of bit lines including the bit line BL11 and the bit line BL12 are sometimes collectively referred to as simply the bit line BL.

The word line WL11 is an example of the first conductive layer. The word line WL21 is an example of the second conductive layer. The bit line BL11 is an example of the third conductive layer.

The word line WL has, for example, a barrier metal layer 11 and a main metal layer 12.

Hereinafter, the x-direction, y-direction, and z-direction shown in FIGS. 56, 57A, and 57B are defined as the first direction, the third direction, and the second direction, respectively. In the present description, the x-direction, y-direction, and z-direction shall include not only the orientations of the arrows in FIGS. 56, 57A, and 57B but also the orientations opposite to the arrow directions.

The word lines WL are alternately stacked with the interlayer insulating layers 150 in the z-direction. The word line WL extends in the x-direction. The word line WL is repeatedly disposed in the y-direction.

The word line WL includes, for example, a metal, a metal nitride, a metal carbide, or a semiconductor. The word line WL has, for example, a barrier metal layer 11 and a main metal layer 12.

The barrier metal layer 11 is, for example, a metal nitride. The barrier metal layer 11 is, for example, titanium nitride, tantalum nitride, tungsten nitride, titanium carbide, tungsten carbide, or tantalum carbide. The main metal layer 12 is, for example, tungsten (W), titanium (Ti), or tantalum (Ta).

The thickness of the word line WL in the z-direction is, for example, equal to or more than 5 nm and equal to or less than 40 nm.

The bit line BL extends in the z-direction. The z-direction intersects the x-direction. The z-direction is orthogonal to the x-direction. The bit line BL is repeatedly disposed in the x-direction and the y-direction.

The bit line BL includes, for example, a metal, a metal nitride, a metal carbide, or a semiconductor. The bit line BL is, for example, titanium nitride, tantalum nitride, tungsten nitride, titanium carbide, tungsten carbide, tantalum carbide, tungsten (W), titanium (Ti), or tantalum (Ta).

The interlayer insulating layer 150 is provided between the word line WL and the word line WL. The interlayer insulating layer 150 includes silicon oxide.

The first insulating film 31 is provided between the bit line BL and the word line WL. The first insulating film 31 is provided between the bit line BL and the interlayer insulating layer 150. The first insulating film 31 is provided between the word line WL11 and the bit line BL11. The first insulating film 31 is provided between the word line WL21 and the bit line BL11.

The first insulating film 31 includes a first oxide containing at least one of hafnium oxide or zirconium oxide. The first insulating film 31 contains orthorhombic crystal. The first insulating film 31 includes the first oxide containing at least one of an orthorhombic hafnium oxide or an orthorhombic zirconium oxide. The first oxide is ferroelectric. The first insulating film 31 is a ferroelectric film.

The first oxide is crystalline. The first insulating film 31 is crystalline.

The main crystal contained in the first oxide is an orthorhombic crystal. Among the crystals contained in the first oxide, the orthorhombic crystal has a proportion higher than that of any of the crystals other than the orthorhombic crystal. The crystals other than the orthorhombic crystal are cubic crystal, hexagonal crystal, tetragonal crystal, monoclinic crystal, or triclinic crystal.

The first oxide is hafnium oxide mainly composed of orthorhombic hafnium oxide, for example. Among the crystals of hafnium oxide contained in the first oxide, the orthorhombic crystal has a proportion higher than that of any of the crystals of hafnium oxide other than the orthorhombic crystal. The hafnium oxide is, for example, hafnium oxide mainly composed of a third orthorhombic (orthorhombic III, space group Pbc2₁, space group number 29).

The first oxide is zirconium oxide mainly composed of orthorhombic zirconium oxide, for example. Among the crystals of zirconium oxide contained in the first oxide, the orthorhombic crystal has a proportion higher than that of any of the crystals of zirconium oxide other than the orthorhombic crystal. The zirconium oxide is, for example, zirconium oxide mainly composed of a third orthorhombic (orthorhombic III, space group Pbc2₁, space group number 29).

The atomic ratio (Zr/(Hf+Zr)) of zirconium (Zr) contained in the first oxide to the total sum of hafnium (Hf) and zirconium (Zr) contained in the first oxide is equal to or more than 50% and equal to or less than 90%.

The first oxide may contain both ferroelectric hafnium oxide and ferroelectric zirconium oxide. The first oxide may be a mixed crystal of, for example, ferroelectric hafnium oxide and ferroelectric zirconium oxide.

The first insulating film 31 contains at least any one impurity element selected from the group consisting of carbon (C), nitrogen (N), chlorine (Cl), boron (B), hydrogen (H), fluorine (F), helium (He), and argon (Ar). The first oxide contains at least any one impurity element selected from the group consisting of carbon (C), nitrogen (N), chlorine (Cl), boron (B), hydrogen (H), fluorine (F), helium (He), and argon (Ar).

Since the first oxide contains the above-described impurity element, it becomes possible to increase the proportion of the orthorhombic crystal in the hafnium oxide or zirconium oxide contained in the ferroelectric region 16a. Since the first oxide contains the above-described impurity element, ferroelectricity becomes likely to be expressed in the hafnium oxide or zirconium oxide contained in the ferroelectric region 16a. It becomes possible to increase the spontaneous polarization amount of ferroelectric hafnium oxide or ferroelectric zirconium oxide.

The concentration of the impurity element in the first insulating film 31 is, for example, equal to or more than 1E19 atoms/cm³ and equal to or less than 2E22 atoms/cm³. The concentration of the impurity element in the first insulating film 31 is, for example, equal to or more than 0.01 atomic % and equal to or less than 20 atomic %.

The unit cell volume of the orthorhombic crystal contained in the first oxide is, for example, equal to or more than 0.1340 nm³ and equal to or less than 0.1370 nm³.

The first oxide contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). Since the first oxide contains the above-described additive element, if the first oxide is hafnium oxide, it becomes possible to increase the proportion of the orthorhombic crystal in the hafnium oxide contained in the first insulating film 31. Since the first oxide contains the above-described additive element, if the first oxide is hafnium oxide, ferroelectricity becomes likely to be expressed in the hafnium oxide contained in the first insulating film 31.

The first insulating film 31 is composed mainly of the first oxide. Being composed mainly of the first oxide means that the mole fraction of the first oxide is the highest among the substances contained in the first insulating film 31. The mole fraction of the first oxide is, for example, equal to or more than 90% and equal to or less than 100%.

The thickness of the first insulating film 31 in the y-direction from the word line WL toward the bit line BL is, for example, equal to or more than 5 nm and equal to or less than 10 nm.

The second insulating film 32 is provided between the first insulating film 31 and the bit line BL. The second insulating film 32 is made of a material different from that of the first insulating film 31. The second insulating film 32 includes the first insulator having a chemical composition different from that of the first oxide.

The first insulator is paraelectric. The second insulating film 32 is a paraelectric film.

The first insulator is amorphous or crystalline. The second insulating film 32 is amorphous or crystalline.

For example, if the first insulator is crystalline, the main crystal contained in the first insulator is, for example, a crystal other than orthorhombic crystal. The crystals other than the orthorhombic crystal are cubic crystal, hexagonal crystal, tetragonal crystal, monoclinic crystal, or triclinic crystal.

The first insulator is an oxide, a nitride, or an oxynitride. The first insulator is, for example, silicon oxide, aluminum oxide, yttrium oxide, or titanium oxide.

The second insulating film 32 is composed mainly of the first insulator. Being composed mainly of the first insulator means that the mole fraction of the first insulator is the highest among the substances contained in the paraelectric region 16b. The mole fraction of the first insulator is, for example, equal to or more than 90% and equal to or less than 100%.

The thickness of the second insulating film 32 in the y-direction from the word line WL toward the bit line BL is, for example, equal to or more than 0.5 nm and equal to or less than 2 nm.

In the FTJ memory of the fifth embodiment, the polarization inversion of the first insulating film 31, which is ferroelectric, is caused by changing the voltage applied between the word line WL and the bit line BL. Depending on the polarization state of the first insulating film 31, the shape of the tunnel barrier formed by the first insulating film 31 and the second insulating film 32 is changed. Due to the change in the shape of the tunnel barrier, the tunnel current flowing through between the word line WL and the bit line BL changes.

For example, if an off state (high-resistance state) where the tunnel current is difficult to flow is defined as data “0”, and an on state (low-resistance state) where the tunnel current is easy to flow is defined as data “1”, the memory cell can store 1-bit data of “0” and “1”.

Next, the functions and effects of the memory device of the fifth embodiment will be described.

In the FTJ memory, it is desirable to increase the tunnel current flowing through in the on state. It is desired to enlarge the difference between the tunnel current flowing in the on state and the tunnel current flowing in the off state, i.e., the so-called memory window.

Enlarging the memory window stabilizes the operation of the FTJ memory, for example. For example, it becomes easy to provide a multivalued FTJ memory.

In the FTJ memory of the fifth embodiment, the first insulating film 31 includes the first oxide containing at least one of an orthorhombic hafnium oxide and or orthorhombic zirconium oxide. Then, the first oxide contains at least any one impurity element selected from the group consisting of carbon (C), nitrogen (N), chlorine (Cl), boron (B), hydrogen (H), fluorine (F), helium (He), and argon (Ar). Since the first insulating film 31 includes the first oxide containing the above-described impurity element, the spontaneous polarization amount of the first insulating film 31 increases. Therefore, it is possible to increase the change amount in the shape of the tunnel barrier formed by the first insulating film 31 and the second insulating film 32. Therefore, it is possible to increase the tunnel current flowing through in the on state. Hence, it is possible to enlarge the memory window of the FTJ memory.

The concentration of the above-described impurity element in the first insulating film 31 is preferably equal to or more than 1E19 atoms/cm³ and equal to or less than 2E22 atoms/cm³, and more preferably equal to or more than 1E20 atoms/cm³ and equal to or less than 2E21 atoms/cm³. By exceeding the above-described lower limit value, the spontaneous polarization amount of the first insulating film 31 increases. By falling below the above-described upper limit value, the gate leakage current via the state due to the impurities in the first insulating film 31 decreases.

The unit cell volume of the orthorhombic crystal contained in the first oxide is preferably equal to or more than 0.1340 nm³, and more preferably equal to or more than 0.1345 nm³. By exceeding the above-described lower limit value, the spontaneous polarization amount of the first insulating film 31 increases.

The unit cell volume of the orthorhombic hafnium oxide and the orthorhombic zirconium oxide that do not contain the above-described impurity element is less than 0.1340 nm³.

The above-described impurity element contained in the first oxide is preferably carbon (C) in particular from the viewpoint of raising the crystallization temperature of the monoclinic in hafnium oxide or zirconium oxide. The above-described impurity element contained in the first oxide is preferably nitrogen (N) from the viewpoint of inactivating the state caused by oxygen deficiency in hafnium oxide or zirconium oxide and suppressing the leakage current. The above-described impurity element contained in the first oxide is preferably hydrogen (H) from the viewpoint of introducing the impurity element into hafnium oxide or zirconium oxide at a high concentration. The above-described impurity element contained in the first oxide is preferably fluorine (F) from the viewpoint that it has high combination energy in hafnium oxide or zirconium oxide and stably exists in hafnium oxide or zirconium oxide. The above-described impurity element contained in the first oxide is preferably helium (He) or argon (Ar) from the viewpoint that a combination state is not formed in hafnium oxide or zirconium oxide and the formation of the state causing generation of the leakage current can be suppressed.

The first oxide is preferably zirconium oxide from the viewpoint of increasing the spontaneous polarization amount of the first insulating film 31.

By lowering the atomic ratio (Zr/(Hf+Zr)), the dielectric constant of the first oxide is lowered, and it is possible to increase the equivalent oxide thickness (EOT) converted into the silicon oxide film of the gate insulating layer 16. The atomic ratio (Zr/(Hf+Zr)) is preferably equal to or less than 75% from the viewpoint of thickening the EOT of the gate insulating layer 16.

By raising the atomic ratio (Zr/(Hf+Zr)), the dielectric constant of the first oxide is raised, and it is possible to decrease the equivalent oxide thickness (EOT) converted into the silicon oxide film of the gate insulating layer 16. The atomic ratio (Zr/(Hf+Zr)) is preferably equal to or less than 65% from the viewpoint of thinning the EOT of the gate insulating layer 16.

The crystallization temperature of zirconium oxide is lower than that of, for example, hafnium oxide. Therefore, monoclinic is likely to be formed during film formation or crystallization. Therefore, adding the above-mentioned impurity element is particularly effective from the viewpoint of increasing the spontaneous polarization amount of zirconium oxide.

If the first oxide is hafnium oxide, the first oxide preferably contains at least one additive element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr). Since hafnium oxide contains the above-mentioned additive element, ferroelectricity becomes likely to be expressed in the hafnium oxide.

If the first oxide is hafnium oxide, the first oxide preferably includes, in particular, zirconium (Zr), yttrium (Y), or lanthanum (La) as an additive element. Hafnium oxide containing zirconium (Zr), yttrium (Y), or lanthanum (La) has a lower crystallization temperature than that containing another additive element. Therefore, monoclinic is likely to be formed during film formation or crystallization. Therefore, adding the above-mentioned impurity element is particularly effective from the viewpoint of increasing the spontaneous polarization amount of hafnium oxide.

Thus, according to the fifth embodiment, since the first insulating film includes the first oxide containing an impurity element, a memory device having a large memory window can be achieved.

In the first to fourth embodiments, the case where the insulating layer is provided between the word lines WL has been described as an example, but there may be a cavity, for example, between the word lines WL.

In the fourth embodiment, the form in which the configurations of the memory devices of the second embodiment and the third embodiment are added to the memory device of the first embodiment has been described. However, for example, it is also possible to provide a form in which only the configuration of the memory device of the second embodiment is added to the memory device of the first embodiment. For example, it is also possible to provide a form in which only the configuration of the memory device of the third embodiment is added to the memory device of the first embodiment. For example, it is also possible to provide a form in which the configuration of the memory device of the third embodiment is added to the memory device of the second embodiment.

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device comprising:
a stacked body including a plurality of insulating layers and a plurality of gate electrode layers, the insulating layers and the gate electrode layers being alternately stacked in a first direction, the gate electrode layers including a first gate electrode layer and a second gate electrode layer adjacent to the first gate electrode layer in the first direction, and the insulating layers including a first insulating layer disposed between the first gate electrode layer and the second gate electrode layer;
a semiconductor layer provided in the stacked body and extending in the first direction; and
a gate insulating layer provided between the semiconductor layer and the first gate electrode layer, the gate insulating layer including a first region including a first oxide containing at least one of hafnium oxide or zirconium oxide, the first region including an orthorhombic crystal, and the first region containing at least one first element selected from the group consisting of carbon (C), nitrogen (N), chlorine (Cl), boron (B), hydrogen (H), fluorine (F), helium (He), and argon (Ar).

2. The memory device according to claim 1, wherein concentration of the at least one first element in the first region is equal to or more than 1E19 atoms/cm³ and equal to or less than 2E22 atoms/cm³.

3. The memory device according to claim 1, wherein a unit cell volume of the orthorhombic crystal contained in the first region is equal to or more than 0.1340 nm³.

4. The memory device according to claim 1, wherein a thickness of the gate insulating layer in a second direction from the first gate electrode layer toward the semiconductor layer is equal to or more than 3 nm and equal to or less than 15 nm.

5. The memory device according to claim 1, wherein an atomic ratio (Zr/(Hf+Zr)) of zirconium (Zr) contained in the first oxide to a total sum of hafnium (Hf) and zirconium (Zr) contained in the first oxide is equal to or more than 50% and equal to or less than 90%.

6. The memory device according to claim 1, wherein the first oxide contains at least one second element selected from the group consisting of silicon (Si), aluminum (Al), zirconium (Zr), yttrium (Y), lanthanum (La), tantalum (Ta), praseodymium (Pr), neodymium (Nd), barium (Ba), magnesium (Mg), gadolinium (Gd), and strontium (Sr).

7. The memory device according to claim 1, wherein the first oxide is ferroelectric.

8. The memory device according to claim 1, wherein the gate insulating layer further including a second region disposed between the first region and the first gate electrode layer, the second region including a first insulator having a chemical composition different from a chemical composition of the first oxide.

9. The memory device according to claim 1, wherein
the first insulating layer includes a second insulator,
the memory device further comprising an intermediate insulating layer provided between the semiconductor layer and the first insulating layer, the intermediate insulating layer including a second oxide including at least one of hafnium oxide or zirconium oxide, the second oxide having a dielectric constant higher than a dielectric constant of the second insulator, and
a thickness of the gate insulating layer in a second direction from the first gate electrode layer toward the semiconductor layer is thicker than a thickness of the intermediate insulating layer in the second direction.

10. A memory device comprising:
a stacked body including a plurality of insulating layers and a plurality of gate electrode layers, the insulating layers and the gate electrode layers alternately stacked in a first direction, the gate electrode layers including a first gate electrode layer and a second gate electrode layer adjacent to the first gate electrode layer in the first direction, and the insulating layers including a first insulating layer disposed between the first gate electrode layer and the second gate electrode layer;
a semiconductor layer provided in the stacked body and extending in the first direction; and
a gate insulating layer provided between the semiconductor layer and the first gate electrode layer, the gate insulating layer including a first region and a second region, the first region including a first oxide containing at least one of hafnium oxide or zirconium oxide, the first region including an orthorhombic crystal, the second region being disposed between the first region and the first gate electrode layer, and the second region including a first insulator having a chemical composition different from a chemical composition of the first oxide.

11. The memory device according to claim 10, wherein the second region is crystalline, and the second region includes a crystal other than orthorhombic crystal.

12. The memory device according to claim 10, wherein the second region is amorphous.

13. The memory device according to claim 10, wherein a thickness of the second region in a second direction from the first gate electrode layer toward the semiconductor layer is thinner than a thickness of the first region in the second direction.

14. The memory device according to claim 10, wherein a thickness of the first region in a second direction from the first gate electrode layer toward the semiconductor layer is equal to or more than 3 nm and equal to or less than 15 nm, and a thickness of the second region in the second direction is equal to or more than 0.5 nm and equal to or less than 15 nm.

15. A memory device comprising:
a stacked body including a plurality of insulating layers and a plurality of gate electrode layers, the insulating layers and the gate electrode layers alternately stacked in a first direction, the gate electrode layers including a first gate electrode layer and a second gate electrode layer adjacent to the first gate electrode layer in the first direction, the insulating layers including a first insulating layer disposed between the first gate electrode layer and the second gate electrode layer, and the first insulating layer including a first insulator;
a semiconductor layer provided in the stacked body and extending in the first direction;
a gate insulating layer provided between the semiconductor layer and the first gate electrode layer, the gate insulating layer including a first region including a first oxide containing at least one of hafnium oxide or zirconium oxide, and the first region including an orthorhombic crystal; and
an intermediate insulating layer provided between the semiconductor layer and the first insulating layer, the intermediate insulating layer including a second oxide containing at least one of hafnium oxide or zirconium oxide, and the second oxide having a dielectric constant higher than a dielectric constant of the first insulator, wherein
a thickness of the gate insulating layer in a second direction from the first gate electrode layer toward the semiconductor layer is thicker than a thickness of the intermediate insulating layer in the second direction.

16. The memory device according to claim 15, wherein the first oxide and the second oxide have an identical chemical composition.

17. The memory device according to claim 15, wherein the gate insulating layer further including a second region disposed between the first region and the first gate electrode layer, the second region including at least one of hafnium oxide or zirconium oxide, and the second region including a third oxide having a chemical composition different from a chemical composition of the first oxide, and the second region includes an orthorhombic crystal.

18. The memory device according to claim 15, wherein a thickness of the gate insulating layer in the second direction is equal to or larger than 1.2 times and equal to or smaller than 5 times a thickness of the intermediate insulating layer in the second direction.

19. The memory device according to claim 15, wherein the intermediate insulating layer is amorphous.

20. The memory device according to claim 15, wherein the intermediate insulating layer is crystalline, and the second oxide includes a crystal other than orthorhombic crystal.
